(19) United States
(12) Patent Application Publication
(10) Pub. No.: US 2014/0361312 A1
(43) Pub. Date: Dec. 11, 2014

(54) SEMICONDUCTOR DEVICE

(71) Applicant: FUJI ELECTRIC CO., LTD., Kawasaki-shi (JP)

(72) Inventors: Koh YOSHIKAWA, Matsumoto-city (JP); Hiroki WAKIMOTO, Matsumoto-city (JP); Masaaki OGINO, Matsumoto-city (JP)

(21) Appl. No.: 14/470,429

(22) Filed: Aug. 27, 2014

Related U.S. Application Data
(63) Continuation of application No. PCT/JP2013/052576, filed on Feb. 5, 2013.

(30) Foreign Application Priority Data
May 15, 2012 (JP) 2012-111192

(51) Int. Cl. H01L 29/06; H01L 29/20

(52) U.S. Cl. CPC H01L 29/0619; H01L 29/0657; H01L 29/0646; H01L 29/2003
USPC 257/76; 257/494

(57) ABSTRACT

In aspects of the invention, SiC reverse blocking MOSFET includes an active region including a MOS gate structure and a breakdown voltage structure portion surrounding the outer circumference of the active region, which are provided on the surface side of a SiC-n⁻ drift layer that is grown on one main surface of a p⁺ SiC substrate. A p-type isolation region is provided on the side surface of the SiC-n⁻ drift layer so as to surround the outer circumference of the breakdown voltage structure portion and to extend from the front surface of the SiC-n⁻ drift layer to the p⁺ SiC substrate. A concave portion which reaches the SiC-n⁻ drift layer through the p⁺ SiC substrate and has a bottom area corresponding to the area of the active region is provided in a region of the other main surface of the p⁺ SiC substrate which is opposite to the active region.

### CROSS-REFERENCE TO RELATED APPLICATIONS

This application is a continuation of International Application No. PCT/JP2013/052576, filed on Feb. 5, 2013, which is based on and claims priority to Japanese Patent Application No. JP 2012-111192, filed on May 15, 2012. The disclosure of the Japanese priority application and the PCT application in their entirety, including the drawings, claims, and the specification thereof, are incorporated herein by reference.

### BACKGROUND

1. Field of the Invention

The present invention relates to semiconductor devices.

2. Related Art

In recent years, a matrix converter, such as a direct-link-type converter circuit, has drawn attention in terms of reducing the size and weight of the circuit, improving efficiency, increasing a response speed, and reducing costs when alternating current (AC)/AC conversion, AC/direct current (DC) conversion, and DC/AC conversion are performed in a power conversion device. The following points are given as an example of the reason. In the general power conversion device including an inverter and a converter, the converter generates a DC intermediate voltage from an AC voltage and the inverter converts the DC intermediate voltage into an AC voltage. A DC smoothing capacitor which smoothes the DC intermediate voltage needs to be provided in an intermediate portion between the converter and the inverter. In addition, the lifespan of the power conversion device tends to be determined by the lifespan of an electric field capacitor which is used as the DC smoothing capacitor. In contrast, since the matrix converter directly generates an AC voltage from an AC voltage, it has a higher power conversion efficiency than the general power conversion device including the inverter and the converter. In addition, since the matrix converter does not generate the DC intermediate voltage, the DC smoothing capacitor is not required.

A preferred device used in the matrix converter is a bidirectional switching element which can control a current in two directions. FIG. 14 is a circuit diagram illustrating an equivalent circuit of a general bidirectional switching element. The bidirectional switching element can be formed by two diodes 1002 and two transistors 1001, as illustrated in the equivalent circuit diagram of FIG. 14(a). In this structure, it is necessary to directly connect the diode 1002 to the transistor 1001 in order to block the reverse voltage applied to the transistor 1001 which is a switching element. For example, a voltage-driven insulated gate bipolar transistor (IGBT) or MOSFET (insulated gate field effect transistor) which can be turned on and off by a gate voltage and whose current can be controlled is preferably used as the transistor 1001.

In the general bidirectional switching element including two transistors 1001 illustrated in FIG. 14(a), the reason why the diode 1002 is needed in order to block the reverse voltage as described above is that the general IGBT or MOSFET is not designed to ensure the reliability of a reverse breakdown voltage (reverse blocking capability) and it is difficult to manufacture the IGBT or the MOSFET such that the reverse blocking capability is ensured. Therefore, for example, in the general IGBT or MOSFET, the breakdown voltage means a forward breakdown voltage. In recent years, a power device has been developed which is called a reverse blocking IGBT (RB-IGBT) having reverse blocking capability in addition to the forward breakdown voltage (forward blocking capability) of the general IGBT. See, for example, Japanese Patent Application Publication No. JP 2002-319676 A (also referred to herein as “Patent Document 1”) at paragraphs [0007] and [0008].

FIG. 14(b) is an equivalent circuit diagram illustrating a bidirectional switching element using the reverse blocking IGBT. The bidirectional switching element illustrated in FIG. 14(b) can be simply formed by connecting two reverse blocking IGBTs 1003 in inverse parallel. The bidirectional switching element including the two reverse blocking IGBTs 1003 illustrated in FIG. 14(b) does not require a diode, as can be seen from the comparison with the bidirectional switching element including two diodes 1002 and two transistors 1001 illustrated in FIG. 14(a). Therefore, the bidirectional switching element illustrated in FIG. 14(b) can reduce power loss and a size corresponding to the diode. The use of the bidirectional switching element illustrated in FIG. 14(b) makes it possible to provide a matrix converter with a small size at a low cost.

An example in which silicon (Si) is used as a substrate material (hereinafter, referred to as a Si substrate) in the reverse blocking IGBT according to the related art (hereinafter, referred to as a silicon reverse blocking IGBT) will be described. FIG. 15 is a cross-sectional view schematically illustrating the structure of the silicon reverse blocking IGBT according to the related art. As illustrated in FIG. 15, an active region 42 in which a main current flows when the silicon reverse blocking IGBT is turned on and a breakdown voltage structure portion 32 which ensures a forward breakdown voltage are provided in a region of the surface of a semiconductor substrate made of silicon which will be an n⁻ drift layer 52. The structure of the active region 42 is basically the same as that of a general IGBT. An emitter electrode 51 comes into ohmic contact with the surface of a p base region 55 and the surface of an n⁺ emitter region 56 and is electrically connected thereto. A gate electrode 58 is formed on the surface of a portion of the p base region 55 which is interposed between the surface of the n⁺ emitter region 56 and the surface of the n⁻ drift layer 52, with a gate insulating film 57 interposed therebetween, to form a MOS gate (metal-oxide film-semiconductor insulated gate) structure. A collector electrode 60 comes into ohmic contact with the surface of a p collector layer 59 which is formed on the rear surface side of the semiconductor substrate and is electrically connected thereto.

A p-type isolation region 53 which comes into contact with the p collector layer 59 provided on the rear surface side of the substrate and a p-type channel stopper region 54 provided on the front surface side of the substrate and extends from the rear surface to the front surface of the substrate so as to connect two main surfaces of the substrate is provided in the side surface of the semiconductor substrate. When the isolation region 53 is formed in this way, a pn junction 61 is formed from the rear surface to the side surface of the semiconductor substrate. The pn junction 61 is a junction surface with a shape that surrounds the MOS gate structure formed in the active region 42 of the device. The pn junction 61 has a function of sustaining the reverse breakdown voltage of the device. Therefore, when the reverse voltage is applied to the device (the voltage applied to an emitter terminal E is higher than the voltage applied to a collector terminal C), a depletion layer 62 which is represented by a dashed line is mainly spread from the pn junction 61 to the n⁻ drift layer 52, with an increase in the applied reverse voltage.

When the reverse voltage is applied, an intersection portion between the end of the depletion layer 62 spread from the pn junction 61 and the front surface of the semiconductor substrate (that is, a portion of the n⁻ drift layer 52 interposed between the p base region 55 and the p-type channel stopper region 54) is protected by an insulating protective film (not illustrated). The region of the front surface of the semiconductor substrate which is protected by the insulating protective film is the breakdown voltage structure portion 32. A technique has been proposed in which a breakdown voltage structure, such as a field limiting ring (FLR) (not illustrated), is provided in the breakdown voltage structure portion 32 to reduce electric field intensity, which is likely to be high in the vicinity of the front surface of the semiconductor substrate, to be less than the electric field intensity of the pn junction 61 in the vicinity of the p collector layer 59 below the active region 42, thereby improving the reliability of the reverse breakdown voltage of the semiconductor device. See, for example, Patent Document 1 and Japanese Patent Application Publication No. JP 2010-258327 A (also referred to herein as “Patent Document 2”) at paragraphs [0004], [0005] and [0021] and FIG. 16.

A silicon carbide (SiC) semiconductor or a gallium nitride (GaN) semiconductor has good characteristics that a band gap is about three times wider than that of a silicon (Si) semiconductor and breakdown field intensity is about ten times higher than that of the Si semiconductor. Therefore, the SiC semiconductor or the GaN semiconductor can have a lower on-voltage and a higher switching speed than the Si semiconductor at the same breakdown voltage. For example, in a power device which uses SiC or GaN as a substrate material (hereinafter, referred to as a SiC substrate or a GaN substrate), the thickness of the n⁻ drift layer 52 (FIG. 15) can be about a tenth of the thickness of the n⁻ drift layer in a power device which uses the Si substrate and has the same breakdown voltage. Specifically, in a vertical power device which uses the SiC substrate or the GaN substrate, the thickness of the n⁻ drift layer 52, that is, the thickness of the substrate can be reduced to about 15 μm required to obtain a breakdown voltage of 1200 V or about 10 μm or less required to obtain a breakdown voltage of 600 V.

However, as described above, SiC or GaN has a wider band gap than Si (hereinafter, referred to as a wide band gap. Therefore, when the SiC substrate or the GaN substrate is used to form an IGBT, the built-in potential (about 3 V) of the pn junction is higher than the built-in potential (about 0.7 V) of the pn junction when the Si substrate is used. It is difficult to obtain a low on-voltage in the device with a breakdown voltage of about 600 V or 1200 V. In order to form a transistor device with the above-mentioned breakdown voltage using the SiC substrate or the GaN substrate, a MOSFET or a junction-field effect transistor (J-FET) has been developed which does not have the pn junction that is traversed by a main current when the semiconductor device is turned on (that is, which is not affected by the built-in potential) or which does not have reverse breakdown voltage characteristics.

The following device has been proposed as another reverse blocking device. A GaN layer is provided on the front surface of a Si substrate which has low resistance and a small thickness, with a buffer layer, such as an aluminum nitride (AlN) layer, interposed therebetween. For example, a MOS gate structure is provided on the surface of the GaN layer (the surface opposite to the Si substrate). A deep trench is formed in the rear surface of the Si substrate so as to reach the GaN layer. The trench is filled with a metal electrode which is provided on the inner wall of the trench to form a Schottky junction and a reverse blocking MOSFET (hereinafter, referred to as a GaN reverse blocking MOSFET) is formed. The GaN reverse blocking MOSFET has a structure in which reverse blocking capability is ensured by the Schottky junction on the bottom of the trench (for example, see the following Patent Document 2).

The following device has been proposed as another reverse blocking device. A high-concentration GaN layer and a low-concentration GaN layer are sequentially formed on the front surface of a Si substrate, with a buffer layer interposed therebetween. A trench is provided in the rear surface of the Si substrate so as to reach the high-concentration GaN layer. The trench is filled with a Schottky barrier metal and a Schottky barrier diode is formed. See, for example, Japanese Patent Application Publication No. JP 2009-54659 A (also referred to herein as “Patent Document 3”) at paragraph [0018] and FIG. 1.

An IGBT having the following structure has been proposed as another reverse blocking device: a trench is provided in the rear surface of a p⁺ Si substrate so as to reach an n⁻ drift layer through a collector layer and a conductor and the n⁻ drift layer which are provided in the trench form a Schottky contact therebetween. See, for example, U.S. Pat. No. 7,132,321 (also referred to herein as “Patent Document 4”) at FIG. 8.

The following diode has been proposed as another reverse blocking device. FIG. 16 is a cross-sectional view illustrating the structure of a p-channel reverse blocking IGBT. FIG. 16 corresponds to FIG. 7 in Japanese Patent Application Publication No. JP 2010-206002 A (also referred to herein as “Patent Document 5”). As illustrated in FIG. 16, a low-concentration p⁻ SiC layer 71 is epitaxially grown on the front surface of an n⁻ SiC substrate 70 which is thick and has low resistance. For example, a MOS gate structure 72 is provided on a surface (a surface opposite to the n⁻ SiC substrate 70) of the low-concentration p⁻ SiC layer 71. A deep trench 73 is provided in the rear surface of the n⁻ SiC substrate 70, which is thick and has low resistance, so as to reach the low-concentration p⁻ SiC layer 71 through the n⁻ SiC substrate 70. A metal electrode 74 is provided along the inner wall of the trench 73 to form a Schottky junction on the surface of the low-concentration p⁻ SiC layer 71. In this way, a p-channel IGBT 1011 is formed (for example, see Patent Document 5).

As another reverse blocking device, a device has been proposed which includes a semiconductor layer that is made of silicon carbide or gallium nitride, has a thickness required for at least a breakdown voltage, and is provided in a central portion of one main surface of a semiconductor substrate and a concave portion that is provided in the other main surface at a position opposite to the central portion, has low on-resistance and high substrate intensity, and reduces the breaking of a wafer in a wafer process. See, for example, Japanese Patent Application Publication No. JP 2007-243080 A (also referred to herein as “Patent Document 6”) at Abstract and FIGS. 1-3.

As another reverse blocking device, a reverse blocking switching element has been proposed which includes a switching element that is made of a wide-band-gap semiconductor and is formed on the front surface of a substrate on which a first terminal is formed, a hetero junction diode that blocks a reverse current and is formed on the rear surface of the substrate on which a second terminal is formed, and a isolation region that is configured by forming a hetero junction on the side surface of the substrate (a cut surface of a chip) so as to extend from the rear surface to the front surface See, for example, Japanese Patent Application Publication No. JP 2007-288172 A (also referred to herein as “Patent Document 7”).

As another reverse blocking device, a device has been proposed in which a MOS gate structure including a gate electrode and an emitter electrode is provided on the front surface side of an n⁻ drift layer, which is a semiconductor substrate having a GaN semiconductor or a SiC semiconductor as a main semiconductor crystal, a cutting surface for chipping includes a p-type isolation region that connects the front surface and the rear surface of the n⁻ drift layer, and a collector electrode that comes into contact with the rear surface of the n⁻ drift layer includes a Schottky metal film. See, for example, Japanese Patent Application Publication No. JP 2009-123914 A (also referred to herein as “Patent Document 8”).

In the following Patent Document 7 and Patent Document 8, when a reverse voltage is applied, a drain potential appears on the front surface of the substrate through the isolation region provided in the side surface of the substrate. The depletion layer is spread from the rear surface to the front surface of the substrate by the junction for ensuring the reverse breakdown voltage which extends from the rear surface of the front surface of the substrate and does not reach the side surface of the substrate. Therefore, a reverse leakage current is reduced. In the following Patent Document 7, a sufficient reverse breakdown voltage is obtained by the reverse breakdown voltage structure including the FLR or the field plate (FP) which is provided on the front surface side of the substrate.

However, the general MOSFET or J-FET does not include the pn junction for ensuring the reverse breakdown voltage and does not have reverse blocking capability. Therefore, a structure has been known in which a Schottky junction between a drain electrode and an n⁻ drift layer is formed on the inner wall of a trench that extends from the rear surface of a substrate to an n⁻ drift layer through a drain layer and is used as a junction for ensuring a reverse breakdown voltage, in order to form the above-mentioned reverse blocking device using, for example, a single MOSFET or a single J-FET. However, when a SiC substrate or a GaN substrate is used to form a device with a breakdown voltage of 600 V to 1200 V, the thickness of the n⁻ drift layer required for the device is only in the range of about 10 μm to 15 μm. Therefore, the thickness of the semiconductor substrate is too small, a wafer is likely to be broken, and it is very difficult to perform a general wafer process.

In the above-mentioned Patent Document 5, the Schottky junction is formed along the inner wall of the deep trench 73 that reaches the low-concentration p⁻ SiC layer 71 through the n⁻ SiC substrate 70 which is thick and has low resistance. Therefore, there is a structural problem that the current or the electric field is likely to be concentrated on the bottom of the trench 73. In addition, it is difficult to remove etching damage on the surface of the low-concentration p⁻ SiC layer 71 which is exposed from the bottom of the trench 73. The etching damage on the surface of the low-concentration p⁻ SiC layer 71 is one of the causes of a reduction in the breakdown voltage. In addition, there is a structural problem that, since the trench 73 has a small width of a few micrometers, it is difficult to form the Schottky junction along the inner wall of the trench 73 after the trench 73 with a high aspect ratio is formed.

In the above-mentioned Patent Document 7, the trench is vertically formed in the front surface of the substrate in the depth direction and the trench is filled with the Si layer to form the isolation region. Therefore, particularly, when a device with a high breakdown voltage is manufactured (produced), the thickness of the semiconductor substrate increases. As a result, the aspect ratio of the trench increases and it is difficult to manufacture the device. Further, in the above-mentioned Patent Document 7, the FLR is provided in the reverse breakdown voltage structure portion by an impurity diffusion method. Therefore, in the device made of a wide-band-gap semiconductor in which impurities are less likely to be diffused, the curvature radius of a pn junction portion of the FLR with the drift layer is reduced and the length of the reverse breakdown voltage structure tends to increase. Furthermore, in the above-mentioned Patent Document 7, the FLRs are provided in both the forward breakdown voltage structure portion and the reverse breakdown voltage structure portion and the n-type high-concentration region which separates the forward breakdown voltage structure portion and the reverse breakdown voltage structure portion is provided at the boundary between the forward breakdown voltage structure portion and the reverse breakdown voltage structure portion. Therefore, there is a problem that the length of the breakdown voltage structure portion increases. In the above-mentioned Patent Document 8, since the reverse breakdown voltage structure portion is not provided, it is difficult to obtain a sufficient reverse breakdown voltage.

### SUMMARY OF THE INVENTION

In order to solve the above-mentioned problems of the related art, an object of the invention is to provide a semiconductor device in which a large amount of current that is sufficient for a power device can flow at a low on-voltage when a semiconductor substrate made of a semiconductor material (wide-band-gap semiconductor), such as SiC or GaN, with a wider band gap than silicon is used and which has high-reliability forward blocking capability and reverse blocking capability.

In order to solve the above-mentioned problems and achieve the object of the invention, a semiconductor device according to an aspect of the invention has the following characteristics. A first-conductivity-type semiconductor layer which is made of a semiconductor material with a wider band gap than silicon is grown on one main surface of a semiconductor substrate of a second conductivity type. An active region which includes an insulated gate structure is formed on a surface of the first-conductivity-type semiconductor layer opposite to the semiconductor substrate. A breakdown voltage structure portion is provided so as to surround the outer circumference of the active region. A concave portion which has an area corresponding to the area of the active region is provided in a region of the other main surface of the semiconductor substrate, which is opposite to the active region, at a depth that reaches the first-conductivity-type semiconductor layer through the semiconductor substrate. A metal film is provided along an inner wall of the concave portion. The metal film comes into contact with the first-conductivity-type semiconductor layer on the bottom of the concave portion to form a Schottky junction.

In the semiconductor device according to the above-mentioned aspect of the invention, an angle that is formed between the surface of the first-conductivity-type semiconductor layer opposite to the semiconductor substrate and an outermost circumferential current path of a main current which flows through the first-conductivity-type semiconductor layer between the active region and the concave portion may be equal to or greater than 45 degrees.

The semiconductor device according to the above-mentioned aspect of the invention may further include a second-conductivity-type isolation layer that is provided in a portion of the first-conductivity-type semiconductor layer, which surrounds the outer circumference of the breakdown voltage structure portion, so as to pass through the first-conductivity-type semiconductor layer in a depth direction and to reach the semiconductor substrate.

In the semiconductor device according to the above-mentioned aspect of the invention, the second-conductivity-type isolation layer may be arranged along a side wall of a trench which is formed at a depth that extends from the other main surface of the semiconductor substrate to the surface of the first-conductivity-type semiconductor layer opposite to the semiconductor substrate.

In the semiconductor device according to the above-mentioned aspect of the invention, the metal film may be provided on the other main surface of the semiconductor substrate and the inner wall of the trench and may be connected to the second-conductivity-type isolation layer on the side wall of the trench.

In the semiconductor device according to the above-mentioned aspect of the invention, the metal film may be arranged along a side wall of a trench which is formed at a depth that extends from the other main surface of the semiconductor substrate to the surface of the first-conductivity-type semiconductor layer opposite to the semiconductor substrate.

In the semiconductor device according to the above-mentioned aspect of the invention, the metal film may come into contact with the first-conductivity-type semiconductor layer on the side wall of the trench to form a Schottky junction.

In the semiconductor device according to the above-mentioned aspect of the invention, the breakdown voltage structure portion may include a forward breakdown voltage structure portion and a reverse breakdown voltage structure portion. The forward breakdown voltage structure portion may include a first junction termination region of the second conductivity type which is provided in a surface layer of the surface of the first-conductivity-type semiconductor layer opposite to the semiconductor substrate and in which a depletion layer is spread from the active region to outer circumference when a forward voltage is applied. The reverse breakdown voltage structure portion may include a second junction termination region of the second conductivity type which is provided in the surface layer of the surface of the first-conductivity-type semiconductor layer opposite to the semiconductor substrate so as to be closer to the outer circumference than the first junction termination region and in which the depletion layer is spread from the outer circumference to the active region when a reverse voltage is applied.

The semiconductor device according to the above-mentioned aspect of the invention may further include: a third junction termination region of the second conductivity type that is provided in the first junction termination region and has a higher impurity concentration than the first junction termination region; and a fourth junction termination region of the second conductivity type that is provided in the second junction termination region and has a higher impurity concentration than the second junction termination region.

In the semiconductor device according to the above-mentioned aspect of the invention, a portion of the first-conductivity-type semiconductor layer which is interposed between the first junction termination region and the second junction termination region may function as both the forward breakdown voltage structure portion and the reverse breakdown voltage structure portion.

In the semiconductor device according to the above-mentioned aspect of the invention, the first-conductivity-type semiconductor layer may be a gallium nitride semiconductor layer.

In the semiconductor device according to the above-mentioned aspect of the invention, the semiconductor device may be an insulated gate field effect transistor having the insulated gate structure including a metal film, an oxide film, and a semiconductor film or the insulated gate structure including a metal film, an insulating film, and a semiconductor film.

According to the semiconductor device of the invention, when the semiconductor substrate made of a wide-band-gap semiconductor, such as SiC or GaN, is used, the metal film which forms the Schottky junction with the first-conductivity-type semiconductor layer is formed on the bottom of the concave portion which extends from the other main surface of the semiconductor substrate to the first-conductivity-type semiconductor layer through the semiconductor substrate. Therefore, a large amount of current which is sufficient for a power device can flow at a low on-voltage and it is possible to ensure high-reliability forward blocking capability and reverse blocking capability.

### BRIEF DESCRIPTION OF DRAWINGS

FIG. 1 is a cross-sectional view schematically illustrating a main portion of an active region of a SiC reverse blocking MOSFET according to Embodiment 1 of the invention;

FIG. 2 is a cross-sectional view schematically illustrating a main process of manufacturing the SiC reverse blocking MOSFET according to Embodiment 1 of the invention (part 1);

FIG. 3 is a cross-sectional view schematically illustrating the main process of manufacturing the SiC reverse blocking MOSFET according to Embodiment 1 of the invention (part 2);

FIG. 4 is a cross-sectional view schematically illustrating the main process of manufacturing the SiC reverse blocking MOSFET according to Embodiment 1 of the invention (part 3);

FIGS. 5A and 5B are cross-sectional views schematically illustrating the main process of manufacturing the SiC reverse blocking MOSFET according to Embodiment 1 of the invention (part 4);

FIG. 6 is a cross-sectional view schematically illustrating the main process of manufacturing the SiC reverse blocking MOSFET according to Embodiment 1 of the invention (part 5);

FIG. 7 is a cross-sectional view schematically illustrating the vicinity of a breakdown voltage structure portion of the SiC reverse blocking MOSFET according to Embodiment 1 of the invention;

FIG. 8 is a plan view illustrating the planar layout of the entire chip of the SiC reverse blocking MOSFET illustrated in FIG. 7;

FIG. 9 is a characteristic diagram illustrating the breakdown voltage characteristics of the SiC reverse blocking MOSFET according to Embodiment 1 of the invention;

FIG. 10 is a characteristic diagram illustrating the I-V characteristics of the SiC reverse blocking MOSFET according to Embodiment 1 of the invention when the SiC reverse blocking MOSFET is turned on;

FIG. 11 is a cross-sectional view illustrating a main portion of an active region of a silicon reverse blocking IGBT according to the related art;

FIG. 12 is a cross-sectional view schematically illustrating the vicinity of a breakdown voltage structure portion of the silicon reverse blocking IGBT according to the related art;

FIG. 13 is a cross-sectional view illustrating a main portion of an active region of a SiC reverse blocking MOSFET according to Embodiment 2 of the invention;

FIGS. 14A and 14B are circuit diagrams illustrating an equivalent circuit of a general bidirectional switching element;

FIG. 15 is a cross-sectional view schematically illustrating the structure of the silicon reverse blocking IGBT according to the related art;

FIG. 16 is a cross-sectional view illustrating the structure of a p-channel reverse blocking IGBT according to the related art;

FIG. 17 is a flowchart illustrating the outline of the main process of manufacturing the SiC reverse blocking MOSFET according to Embodiment 1 of the invention;

FIG. 18 is a cross-sectional view illustrating the structure of a wide-band-gap reverse blocking MOS semiconductor device according to Embodiment 3 of the invention;

FIG. 19 is an enlarged cross-sectional view illustrating a breakdown voltage structure portion illustrated in FIG. 18;

FIG. 20 is a cross-sectional view illustrating a breakdown voltage structure portion of a wide-band-gap reverse blocking MOS semiconductor device according to the related art;

FIG. 21 is a cross-sectional view illustrating a breakdown voltage structure portion of a wide-band-gap reverse blocking MOS semiconductor device according to Embodiment 4 of the invention;

FIG. 22 is a cross-sectional view illustrating a breakdown voltage structure portion of a wide-band-gap reverse blocking MOS semiconductor device according to Embodiment 5 of the invention;

FIG. 23 is a cross-sectional view illustrating the structure of a wide-band-gap reverse blocking MOS semiconductor device according to Embodiment 6 of the invention; and

FIG. 24 is an enlarged cross-sectional view illustrating a breakdown voltage structure portion illustrated in FIG. 23.

### DETAILED DESCRIPTION

Hereinafter, preferred embodiments of a semiconductor device according to the invention will be described in detail with reference to the accompanying drawings. The invention is not limited to the following embodiments as long as it does not depart from the scope and spirit thereof. In the specification and the accompanying drawings, in the layers or regions having “n” or “p” appended thereto, an electron or a hole means a majority carrier. In addition, symbols “+” and “−” added to n or p mean that impurity concentration is higher and lower than that of the layer without the symbols. In the description of the following embodiments and the accompanying drawings, the same components are denoted by the same reference numerals and the description thereof will not be repeated. In addition, in the accompanying drawings described in the embodiments, for ease of viewing or understanding of the structure of the invention, the scale and dimensional ratio are different from the actual scale and dimensional ratio.

### Embodiment 1

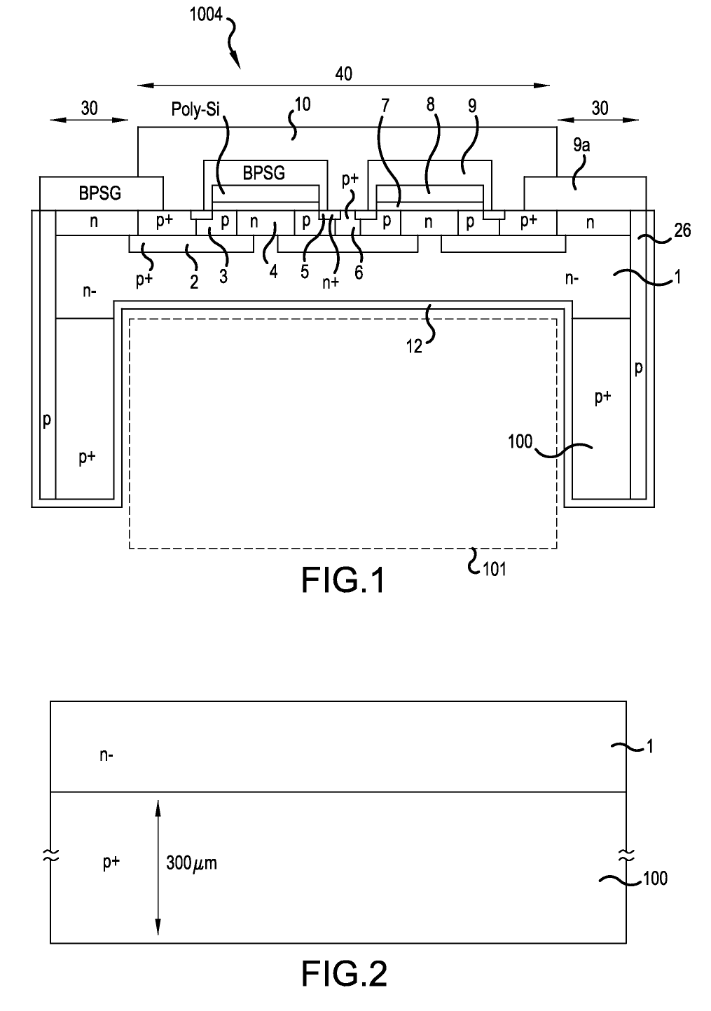

A reverse blocking insulated gate semiconductor device (wide-band-gap reverse blocking MOS semiconductor device) according to Embodiment 1 of the invention which is made of a semiconductor material having a wider band gap than silicon will be described in detail with reference to FIGS. 1 to 6. First, the structure of a reverse blocking MOSFET (hereinafter, referred to as a SiC reverse blocking MOSFET) using silicon carbide (SiC) as a semiconductor material, which is an example of the wide-band-gap reverse blocking MOS semiconductor device according to Embodiment 1, will be described. FIG. 1 is a cross-sectional view schematically illustrating a main portion of an active region of the SiC reverse blocking MOSFET according to Embodiment 1 of the invention. FIG. 1 illustrates a main portion around an active region 40 in a SiC reverse blocking MOSFET 1004.

As illustrated in FIG. 1, the SiC reverse blocking MOSFET 1004 according to Embodiment 1 includes a p⁺ SiC substrate 100 and a SiC-n⁻ drift layer 1 which is formed on one main surface of the p⁺ SiC substrate 100 so as to come into contact therewith and has a lower concentration than the p⁺ SiC substrate 100. A SiC-p⁺ base region 2 is selectively formed in a surface layer (a surface layer opposite to the p⁺ SiC substrate 100) of the SiC-n⁻ drift layer 1 by ion implantation.

A SiC-p epitaxial layer is deposited on the surface of the SiC-n⁻ drift layer 1 so as to cover the SiC-p⁺ base region 2. A SiC-p epitaxial region 3, a SiC-n J-FET region 4, a SiC-n⁺ source region 5, and a SiC-p⁺ body region 6 forming a portion of a MOS gate (metal-oxide-semiconductor insulated gate) structure are arranged in a predetermined pattern in the SiC-p epitaxial layer by selective ion implantation.

A poly-Si gate electrode 8 is provided on the surfaces of the SiC-p epitaxial regions 3 (the surfaces opposite to the SiC-n⁻ drift layer 1), which are arranged on both sides of the SiC-n J-FET region 4 such that the SiC-n J-FET region 4 is interposed therebetween, with a gate insulating film 7 interposed therebetween. The poly-Si gate electrode 8 is covered by a source electrode 10, with boro-phospho-silicate glass (BPSG; interlayer insulating film) 9 interposed therebetween. The source electrode 10 comes into contact with the SiC-n⁺ source region 5 and the SiC-p⁺ body region 6 through an opening portion provided in the BPSG 9 and is electrically connected to the SiC-p⁺ base region 2 below the SiC-n⁺ source region 5 and the SiC-p⁺ body region 6.

A concave portion 101 is provided in the p⁺ SiC substrate 100 at a depth that extends from the other main surface (rear surface) opposite to an active region 40, in which the MOS gate structure is formed, to the SiC-n⁻ drift layer 1 through the p⁺ SiC substrate 100. The area of the concave portion 101 is substantially equal to the area of a region (that is, the active region 40) in which the MOS gate structure is formed. The area of the concave portion 101 means the area of a lower portion (bottom) of the concave portion 101. The concave portion 101 will be described in detail below. A conductive film (metal film) which will be a drain electrode 12 is provided on the other main surface including the inner wall of the concave portion 101. The metal film, which will be the drain electrode 12, forms a Schottky junction with the SiC-n⁻ drift layer 1 and functions as a Schottky electrode. The metal film is obtained by forming a titanium (Ti) film made of, for example, a Schottky barrier metal material using sputtering and sequentially forming a nickel (Ni) film and a gold (Au) film on the titanium film using plating.

A breakdown voltage structure portion 30 is provided on the surface (the surface opposite to the p⁺ SiC substrate 100) of the SiC-n⁻ drift layer 1 so as to surround the outer circumference of the active region 40 which is close to the MOS gate structure. A p-type isolation region 26 is provided in the outer circumference of the breakdown voltage structure portion 30 so as to surround the breakdown voltage structure portion 30 and to extend from the surface (the surface opposite to the p⁺ SiC substrate 100) of the SiC-n⁻ drift layer 1 to the p⁺ SiC substrate 100 through the SiC-n⁻ drift layer 1. The p-type isolation region 26 may extend from the surface of the SiC-n⁻ drift layer 1 to the rear surface of the p⁺ SiC substrate 100. The BPSG 9 is provided on the SiC-n⁻ drift layer 1 in the breakdown voltage structure portion 30. In the breakdown voltage structure portion 30, the BPSG 9 which covers the SiC-n⁻ drift layer 1 functions as a field insulating film (insulating protective film) 9a.

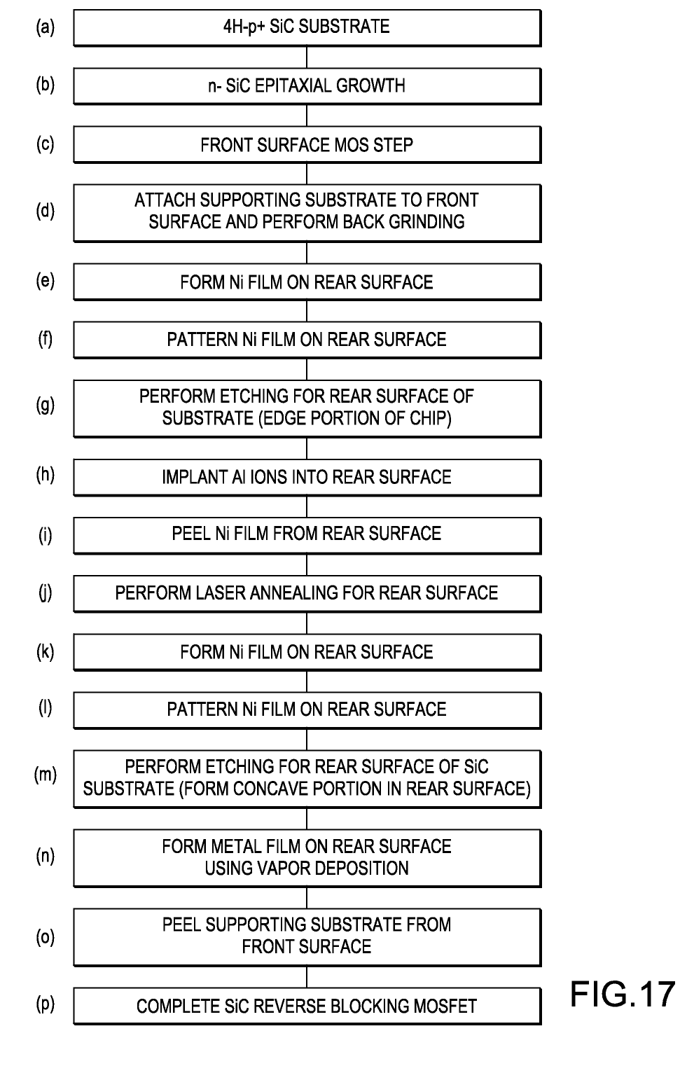

Next, a method for manufacturing the SiC reverse blocking MOSFET 1004 according to Embodiment 1 of the invention will be described. FIGS. 2 to 6 are cross-sectional views schematically illustrating the main processes of manufacturing the SiC reverse blocking MOSFET according to Embodiment 1 of the invention. FIG. 17 is a flowchart illustrating the outline of the main processes of manufacturing the SiC reverse blocking MOSFET according to Embodiment 1 of the invention. First, a 4H-p⁺ SiC substrate 100 which has a diameter of 75 mm and a thickness of 300 μm and has the (0001) Si plane as the main surface is prepared (FIG. 17, step (a)). Then, the SiC-n⁻ drift layer 1 is epitaxially grown with a thickness of 15 μm on one main surface (front surface) of the p⁺ SiC substrate 100 by a chemical vapor deposition (CVD) method which is a known technique (FIG. 17, step (b)). FIG. 2 illustrates this state.

In the process illustrated in FIG. 17, step (b), the impurity concentration of the SiC-n⁻ drift layer 1 was, for example, 1.8×10¹⁶ cm⁻³. For example, silane (SiH₄) gas is used as a silicon material for epitaxial growth for forming the SiC-n⁻ drift layer 1 and propane (C₃H₈) gas is used as a carbon material. In addition, for example, arsine (AsH₃) gas and stibine (SbH₃) gas are used as a dopant material in order to change an epitaxial layer, which will be the SiC-n⁻ drift layer 1, into an n-type layer.

Then, a photoresist pattern (not illustrated) in which a portion corresponding to the region in which the SiC-p⁺ base region 2 is formed is opened in a predetermined pattern is formed on the surface of the SiC-n⁻ drift layer 1 by a photolithography process. For example, aluminum (Al) ions are radiated with a dose of about 1×10¹⁵ cm⁻² at a temperature of 600° C. using the photoresist pattern as a mask and are selectively implanted into the SiC-n⁻ drift layer 1. After the photoresist pattern is removed, rapid thermal annealing (hereinafter, referred to as RTA) is performed at a temperature of 1700° C. for about 2 minutes to activate the Al ions implanted into the SiC-n⁻ drift layer 1. In this way, the SiC-p⁺ base region 2 is formed in a predetermined pattern.

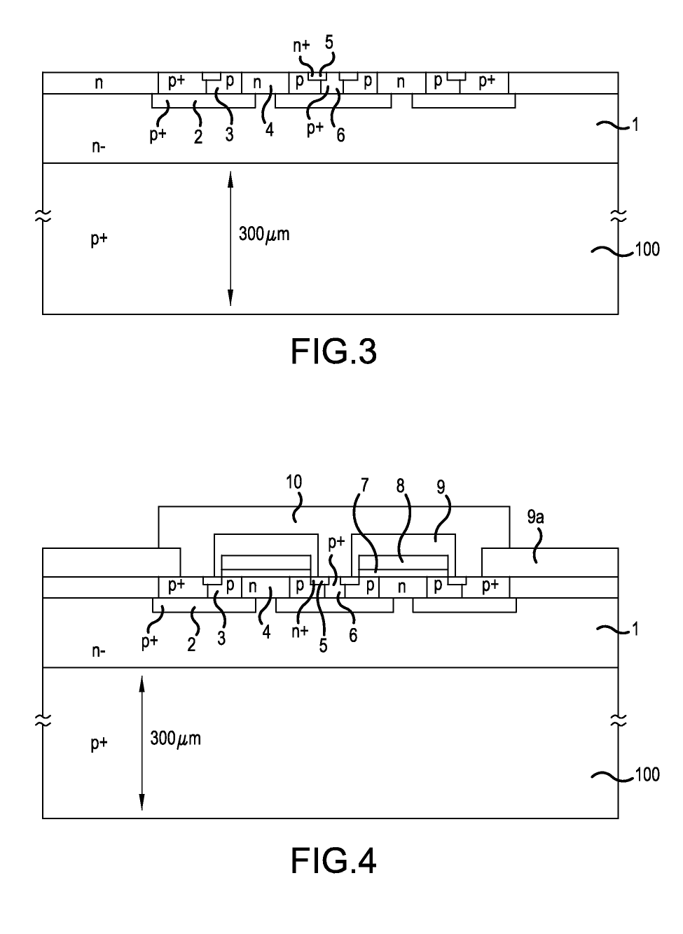

Then, the SiC-p epitaxial region 3 is epitaxially grown by the CVD method and is deposited with a thickness of 1 μm to 5 μm on the entire surface of the SiC-n-drift layer 1. In the epitaxial growth for forming the SiC-p epitaxial region 3, for example, trimethyl indium (In(CH₃)₃) is used as a dopant gas and the impurity concentration of the SiC-p epitaxial region 3 is 5×10¹⁵ cm⁻³. Then, the SiC-n J-FET region 4, the SiC-n⁺ source region 5, and the SiC-p⁺ body region 6 are sequentially formed in a predetermined pattern on the surface of the SiC-p epitaxial region 3 by a photolithography process, a high-temperature ion implantation process, and an RTA process. FIG. 3 illustrates this state.

The order in which the SiC-n J-FET region 4, the SiC-n⁺ source region 5, and the SiC-p⁺ body region 6 are formed may be changed. For example, the impurity concentration of the SiC-n J-FET region 4 is about 2×10¹⁶ cm³, the impurity concentration of the SiC-n⁺ source region 5 is about 3×10²⁰ cm⁻³, and the impurity concentration of the SiC-p⁺ body region 6 is about 1×10¹⁹ cm⁻³. Ion implantation for forming the SiC-n J-FET region 4 and the SiC-p⁺ body region 6 is performed at an acceleration energy of, for example, 40 keV to 460 keV such that ion species reach a deep region.

The RTA process is performed, for example, at a temperature of 1700° C. for 2 minutes. In addition, the RTA process may be performed for each ion implantation process for forming the SiC-n J-FET region 4, the SiC-n⁺ source region 5, and the SiC-p⁺ body region 6, or it may be performed once after all of the ion implantation processes end. Then, after the RTA process is performed, a heat treatment is performed for a semiconductor substrate (hereinafter, referred to as a SiC substrate), which is a laminate of the p⁺ SiC substrate 100, the SiC-n⁻ drift layer 1, and the SiC-p epitaxial region 3, in an oxygen atmosphere to form the gate insulating film 7 with a thickness of 70 nm on a surface (hereinafter, referred to as a front surface) of the SiC substrate which is close to the SiC-p epitaxial region 3.

Then, a high-impurity-concentration polysilicon film is formed with a thickness of 0.5 μm on the gate insulating film 7 by the CVD method. Then, the high-impurity-concentration polysilicon film is etched in a predetermined pattern by a photolithography process and an etching process to form the poly-Si gate electrode 8. In this way, the MOS gate structure including the SiC-n J-FET region 4, the SiC-n⁺ source region 5, the SiC-p⁺ body region 6, the gate insulating film 7, and the poly-Si gate electrode 8 is formed on the surface of the SiC substrate which is close to the SiC-p epitaxial region 3 (FIG. 17, step (c)).

Then, the BPSG 9 which has a thickness of 1.0 μm and covers the poly-Si gate electrode 8 is formed as an interlayer insulating film by the CVD method. Then, the BPSG 9 is patterned by the photolithography process and the etching process to form an opening pattern, through which the surface of the SiC-n⁺ source region 5 and the surface of the SiC-p⁺ body region 6 are selectively exposed, in the BPSG 9. Then, a laminated film of a nickel (Ni) film and a titanium (Ti) film is formed as the source electrode 10 so as to come into ohmic contact with the surface of the SiC-n⁺ source region 5 and the surface of the SiC-p⁺ body region 6. FIG. 4 illustrates this state.

Then, a supporting substrate (not illustrated) is attached to the surface of the p⁺ SiC substrate 100 (that is, the front surface of the SiC substrate) which is close to the MOS gate structure and the rear surface of the p⁺ SiC substrate 100 with a thickness of 300 μm is ground such that the thickness of the p⁺ SiC substrate 100 is reduced to, for example, 50 μm (FIG. 17, step (d)). In Embodiment 1, back grinding is performed in order to reduce the time required for a trench etching process for the rear surface of the p⁺ SiC substrate 100, which is a post-process. However, when the thickness of the p⁺ SiC substrate 100 before the back grinding process is sufficiently less than 300 μm, for example, close to 50 μm, the back grinding process may be omitted.

Then, a nickel film 11 with a thickness of about 1 μm is formed on the entire ground rear surface of the p⁺ SiC substrate 100, with the supporting substrate (not illustrated), which is attached to the surface of the p⁺ SiC substrate 100 close to the MOS gate structure, remaining (FIG. 17, step (e)). Then, the nickel film 11 in an element inner circumferential portion 13 remains as a mask and the nickel film 11 in an element peripheral portion 14 is removed by the photolithography process and the etching process (FIG. 17, step (f)). Then, etching is performed for the rear surface of the p⁺ SiC substrate 100 using the remaining portion of the nickel film 11 as an etching mask to form a trench groove 105 which extend to the front surface of the SiC substrate in the element peripheral portion 14 of the p⁺ SiC substrate 100 (FIG. 17, step (g)). The element inner circumferential portion 13 is a portion in which the active region 40, the breakdown voltage structure portion 30, and the p-type isolation region 26 are formed. The element peripheral portion 14 is a portion which surrounds the outer circumference of the element inner circumferential portion 13. A chip edge portion (the side surface of a chip) is exposed from the element peripheral portion 14.

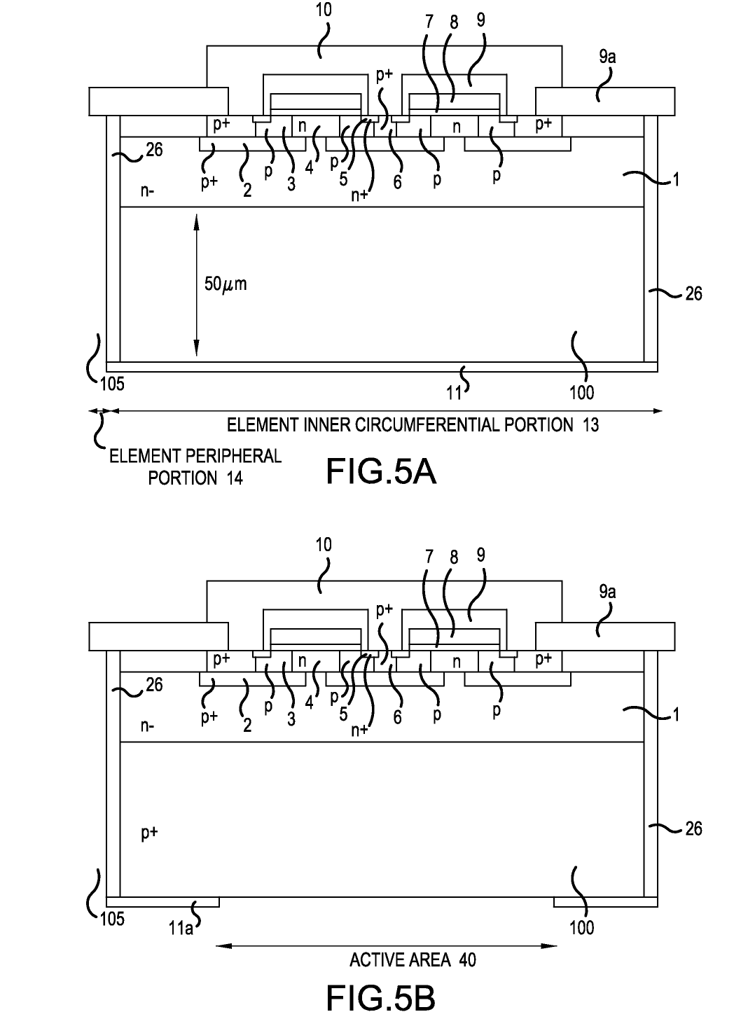

Then, an oblique ion implantation process and a laser annealing process are performed for the rear surface of the p⁺ SiC substrate 100, using the remaining portion of the nickel film 11, which is used as an etching mask for the trench groove 105, as an ion implantation mask (FIG. 17, step (j)), to form the p-type isolation region 26 on the side wall of the trench groove 105 (FIG. 17, step (h)). At that time, the entire nickel film 11 on the rear surface of the p⁺ SiC substrate 100 is removed after the oblique ion implantation process and before the laser annealing process (FIG. 17, step (i)). The impurity concentration of the p-type isolation region 26 is, for example, about 1×10¹⁸ cm⁻³. Ion implantation is performed for the p-type isolation region 26 at three acceleration energy levels of, for example, 40 keV, 100 keV, and 150 keV such that ion species reach a relative deep region. FIG. 5(a) illustrates this state.

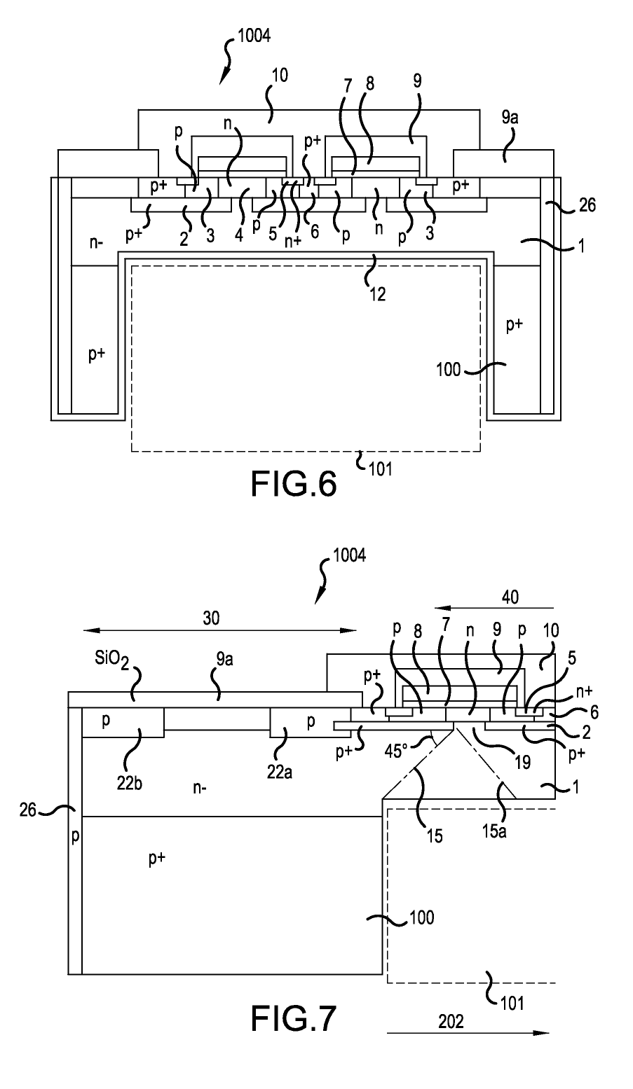

Then, a nickel film 11a is deposited with a thickness of about 1 μm on the rear surface of the p⁺ SiC substrate 100 (FIG. 17, step (k)). Then, a portion of the nickel film 11a on the rear surface of the substrate, which corresponds to the active region 40, is removed by the photolithography process and the etching process and a portion of the nickel film 11a on the rear surface of the substrate, which corresponds to the outer circumferential portion surrounding the active region 40, remains (FIG. 17. step (I)). FIG. 5(b) illustrates this state. Then, etching is performed for the rear surface of the p⁺ SiC substrate 100, using the remaining portion of the nickel film 11a as an etching mask, to form the concave portion 101 in a portion of the rear surface of the substrate corresponding to the active region 40 in the element inner circumferential portion 13 (FIG. 17, step (m)). At that time, the etching depth of the concave portion 101 is greater than the thickness of the p⁺ SiC substrate 100 and the concave portion 101 reaches the SiC-n⁻ drift layer 1. Therefore, the SiC-n⁻ drift layer 1 appears at the end (bottom) of the concave portion 101. Then, the nickel film 11a is removed and a Ti film, a Ni film, and an Au film are sequentially formed as the drain electrode 12 on the rear surface of the p⁺ SiC substrate 100 (including the inner wall of the concave portion 101) by vapor deposition (FIG. 17, step (n)). FIG. 6 illustrates this state. Then, the supporting substrate on the front surface side of the SiC substrate peels off (FIG. 17, step (o)). In this way, the SiC reverse blocking MOSFET 1004 according to Embodiment 1 is completed (FIG. 17, step (p)).

In the SiC reverse blocking MOSFET 1004, the Ti film which is formed as the drain electrode 12 on the inner wall of the concave portion 101 and the SiC-n⁻ drift layer 1 form a Schottky junction. When a voltage (that is, a reverse voltage) is applied between the drain electrode 12 and the source electrode 10 such that the potential of the drain electrode 12 is negative, the Schottky junction sustains the reverse voltage. As such, in the SiC reverse blocking MOSFET 1004 according to Embodiment 1, the concave portion 101 is formed in a portion of the rear surface of the p⁺ SiC substrate 100, which corresponds to the active region 40, at a depth that reaches the SiC-n⁻ drift layer 1 and the Ti film which forms the Schottky junction with the flat SiC-n⁻ drift layer 1 is provided at the leading end (bottom) of the concave portion 101. In this way, the effect of preventing the concentration of a current or the concentration of the electric field is obtained.

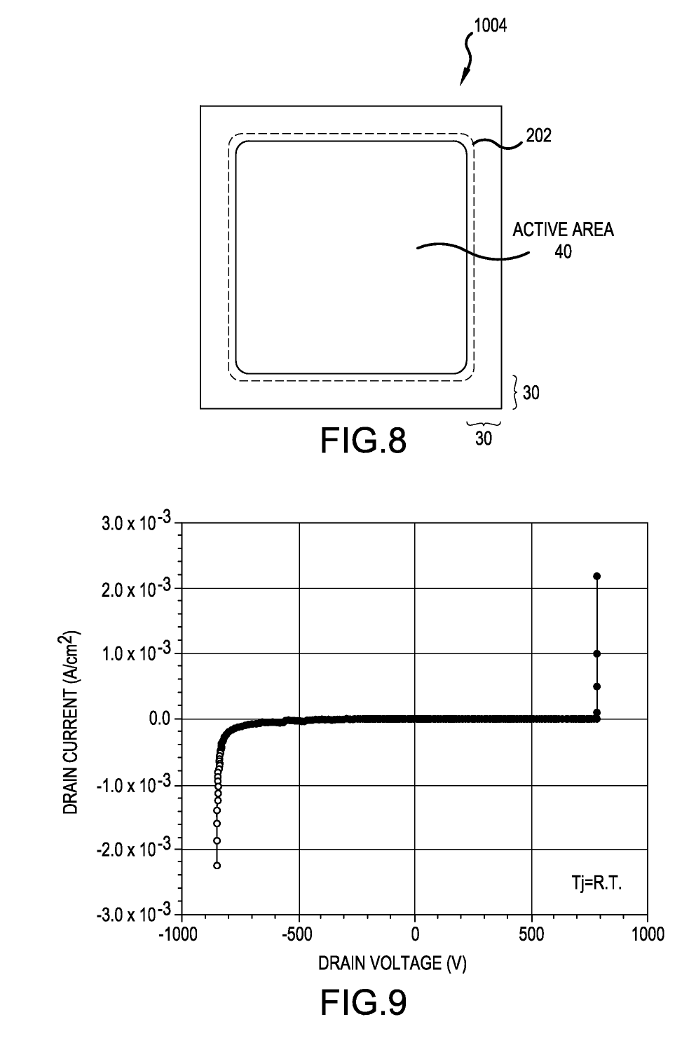

FIG. 7 is a cross-sectional view schematically illustrating the vicinity of the breakdown voltage structure portion in the SiC reverse blocking MOSFET according to Embodiment 1 of the invention. FIG. 7 illustrates the cross-sectional structure of the chip end side of the SiC substrate (chip) including a portion of the active region 40 and the breakdown voltage structure portion 30 in the SiC reverse blocking MOSFET 1004. FIG. 8 is a plan view illustrating the planar layout of the entire chip of the SiC reverse blocking MOSFET illustrated in FIG. 7. Hereinafter, the concave portion 101 which is formed in the rear surface of the SiC substrate in the depth direction of the substrate by etching will be described. As illustrated in FIG. 7, in the invention, it is preferable that the concave portion 101 be arranged such that the angle formed between the surface of the substrate and a one-dot chain line 15 connecting the outer end of an opening portion 19 in the outermost circumference of the SiC-p⁺ base region 2 and the outermost circumferential end of the bottom of the concave portion 101 is equal to or greater than 45 degrees. The opening portion 19 of the SiC-p⁺ base region 2 is a portion of the SiC-n⁻ drift layer 1 which is interposed between adjacent SiC-p⁺ base regions 2 and has a predetermined width and in which the SiC-p⁺ base region 2 is not provided. As described above, the concave portion 101 has a depth that extends from the rear surface of the SiC substrate to the SiC-n⁻ drift layer 1 through the p⁺ SiC substrate 100. Therefore, when the concave portion 101 is arranged in this way, it is possible to prevent a current from being concentrated on the MOS gate structure on the outer circumferential side through the opening portion 19 which is arranged outside the opening portion 19 disposed in the outermost circumference. When the angle formed between the one-dot chain line 15 and the front surface of the substrate is close to 45 degrees and is equal to or less than 90 degrees, the area 202 of the concave portion 101 (dashed line) formed in the rear surface of the substrate is greater than the area of the active region 40 in which a main current flows, as illustrated in the top view of the SiC reverse blocking MOSFET 1004 illustrated in FIG. 8. When the angle is further increased as represented by a one-dot chain line 15a, the area 202 of the concave portion 101 (dashed line) is less than the area of the active region 40. This structure is also included in the invention. When the angel between the one-dot chain line 15 and the front surface of the substrate is close to 45 degrees, the same effect as described above is obtained.

The breakdown voltage structure portion 30 is formed so as to surround the outer circumference of the active region 40. As illustrated in FIG. 7, the breakdown voltage structure portion 30 includes a junction termination extension (JTE) including SiC-p junction termination extension regions 22a and 22b which have a function of reducing the electric field and the insulating protective film 9a, such as a SiO₂ film, which protects the front surface of the breakdown voltage structure portion 30. The SiC-p junction termination extension region 22a is formed so as to come into contact with the SiC-p⁺ base region 2 arranged in the outermost circumference of the MOS gate structure. The SiC-p junction termination extension region 22b is formed in the breakdown voltage structure portion 30 so as to come into contact with the inner circumference of the p-type isolation region 26 formed in the outermost circumference of the breakdown voltage structure portion 30. The formation of the p-type isolation region 26 and the SiC-p junction termination extension regions 22a and 22b makes it easy to spread the depletion layer and makes it possible to improve the forward and reverse breakdown voltages, to increase the voltage applied, and to prevent the spread depletion layer from coming into direct contact with a cut portion of the end surface (side surface) of the chip. As a result, it is possible to maintain a high-reliability reverse breakdown voltage.

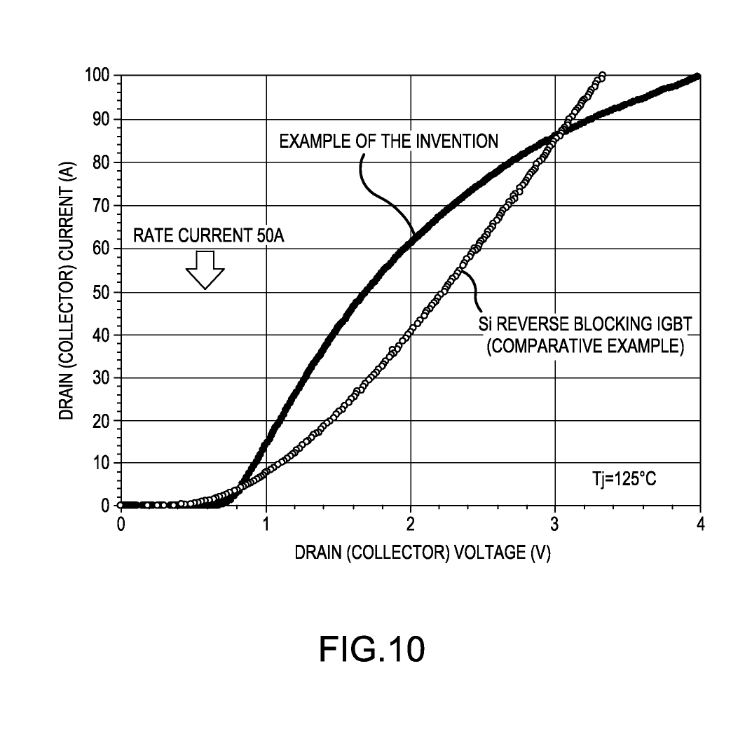

FIG. 9 is a characteristic diagram illustrating the breakdown voltage characteristics of the SiC reverse blocking MOSFET according to Embodiment 1 of the invention. FIG. 10 is a characteristic diagram illustrating current-voltage characteristics (I-V characteristics) of the SiC reverse blocking MOSFET according to Embodiment 1 of the invention when the SiC reverse blocking MOSFET is turned on. The forward breakdown voltage of the SiC reverse blocking MOSFET 1004 according to Embodiment 1 of the invention is about 750 V and the reverse breakdown voltage (not illustrated) thereof is about 850 V. Therefore, the SiC reverse blocking MOSFET 1004 has sufficient blocking characteristics as an element with a breakdown voltage of 600 V. An element (example) which was used in the present measurement had a chip size of 5 mm×5 mm and a rated current of 50 A (the area of the active region=0.2 cm² and rated current density=250 A/cm²). For comparison, FIG. 10 illustrates current-voltage characteristics of a general silicon reverse blocking IGBT 1010 (comparative example) with a rated voltage of 600 V and a rated current of 50 A (a rated current density of 200 A/cm²) when the silicon reverse blocking IGBT 1010 is turned on. In the example illustrated in FIG. 9, a junction temperature Tj was a room temperature (about 25° C.). In the example and the comparative example illustrated in FIG. 10, the junction temperature Tj was 125° C.

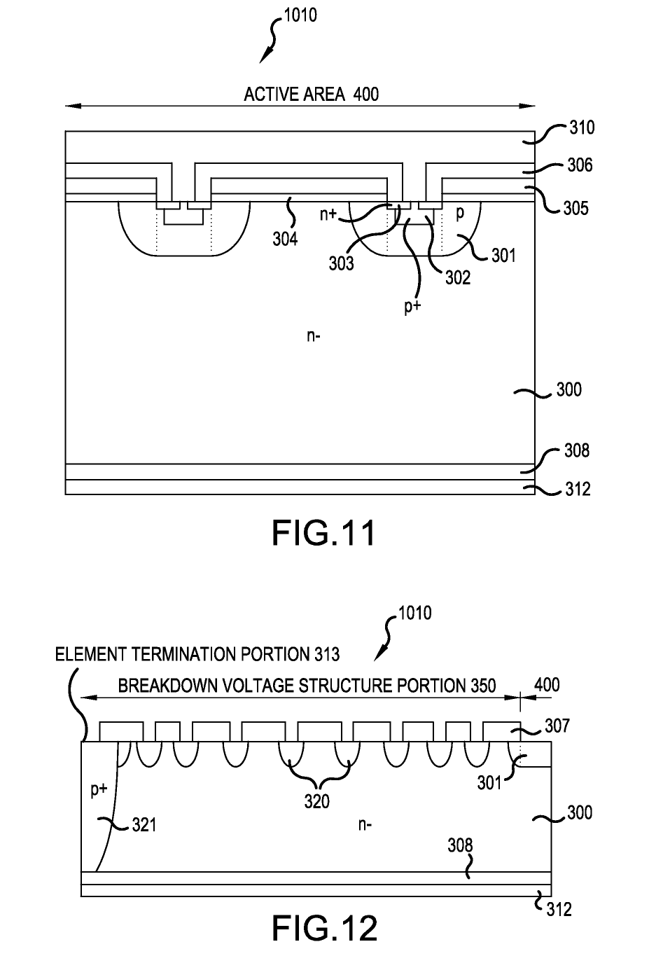

An active region 400 and a breakdown voltage structure portion 350 which surrounds the outer circumference of the active region 400 in the silicon reverse blocking IGBT 1010 used for comparison will be described with reference to FIGS. 11 and 12. FIG. 11 is a cross-sectional view illustrating a main portion of the active region of the silicon reverse blocking IGBT according to the related art. FIG. 12 is a cross-sectional view schematically illustrating the vicinity of the breakdown voltage structure portion of the silicon reverse blocking IGBT according to the related art. As illustrated in FIG. 11, the active region 400 includes a p-type base region 301 which is formed in one main surface of an n⁻ drift layer 300, and an n-type emitter region 303 and a p⁺ body region 302 which are formed in a surface layer of the p-type base region 301. A plurality of the p-type base regions 301 are provided in an island-shaped or stripe-shaped planer pattern in the active region 400.

In each of the p-type base regions 301, a gate electrode 305, which is, for example, a polysilicon film, is formed on the surface of a portion of the p-type base region 301 interposed between the n-type emitter region 303 and an n⁻ drift layer 300, with a gate insulating film 304 interposed therebetween, to form a front-surface-side MOS gate structure. The gate insulating film 304 and the gate electrode 305 form a MOS gate structure common to adjacent p-type base regions 301 in the surface of the substrate. An emitter electrode 310 which comes into conductive contact with both the n-type emitter region 303 and the p⁺ body region 302 through an opening portion of an interlayer insulating film 306 are formed on the surfaces of the n-type emitter region 303 and the p⁺ body region 302. A collector region 308 and a collector electrode 312 are formed on the other main surface of the n⁻ drift layer 300.

As illustrated in FIG. 12, the breakdown voltage structure portion 350 has an electric field reducing mechanism, such as a plurality of annular FLRs 320 which are formed in the outer circumference of the active region 400. An insulating protective film 307 is formed on the surface of a portion of the n⁻ drift layer 300 which is interposed between adjacent FLRs 320. A p⁺ junction isolation region 321 is formed in an element termination portion 313 provided in the outermost circumference of the breakdown voltage structure portion 350 at a depth that extends from the front surface (one main surface of the n⁻ drift layer 300) of the substrate to the collector region 308 in the rear surface of the substrate (the other main surface of the n⁻ drift layer 300). The thickness of the n⁻ drift layer 300 is about 100 μm when the breakdown voltage of the silicon reverse blocking IGBT 1010 is 600 V.

A turn-off loss Eoff at the junction temperature Tj, 125° C., of the SiC reverse blocking MOSFET 1004 according to Embodiment 1 of the invention was 1.9 mJ. In contrast, the turn-off loss Eoff at the junction temperature Tj, 125° C., of the silicon reverse blocking IGBT 1010 according to the comparative example was 2.0 mJ. It was verified that the on-voltage of the SiC reverse blocking MOSFET 1004 was 1.62 V which was significantly lower than that of the on-voltage, 2.20 V, of the silicon reverse blocking IGBT 1010 according to the comparative example and it was possible to reduce the on-voltage. In addition, in the SiC reverse blocking MOSFET 1004 according to the invention, as described above, the on-voltage is reduced. Therefore, the SiC reverse blocking MOSFET with the structure in which the trench (concave portion 101) is provided in a portion of the rear surface of the substrate corresponding to the active region 40, the Schottky junction is formed at the bottom of the trench, and the metal film forming the Schottky junction is used as the drain electrode 12 sufficiently functions as a vertical switching device with voltage characteristics capable of achieving an effective forward blocking capability and an effective reverse blocking capability.

As described above, according to Embodiment 1, the drain electrode which forms the Schottky junction with the n⁻ drift layer is formed on the bottom of the concave portion that extends from the rear surface of the SiC substrate to the n⁻ drift layer through the p⁺ SiC substrate. Therefore, a large amount of current which is sufficient for a power device can flow at a low on-voltage and it is possible to ensure high-reliability forward blocking capability and reverse blocking capability.

### Embodiment 2

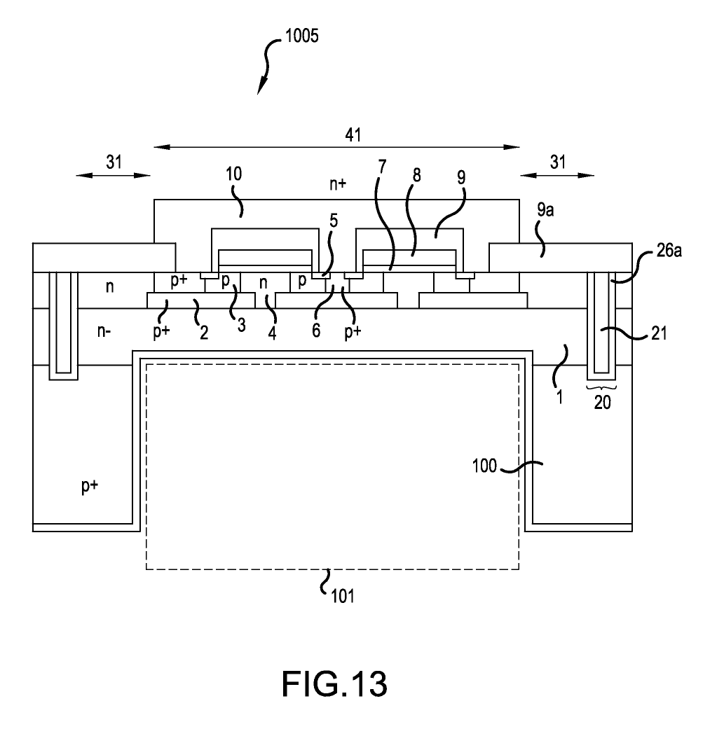

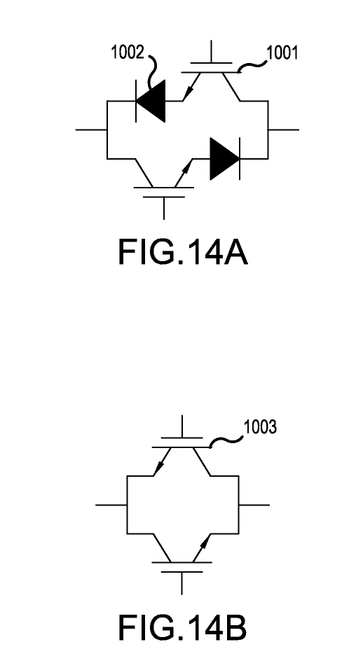

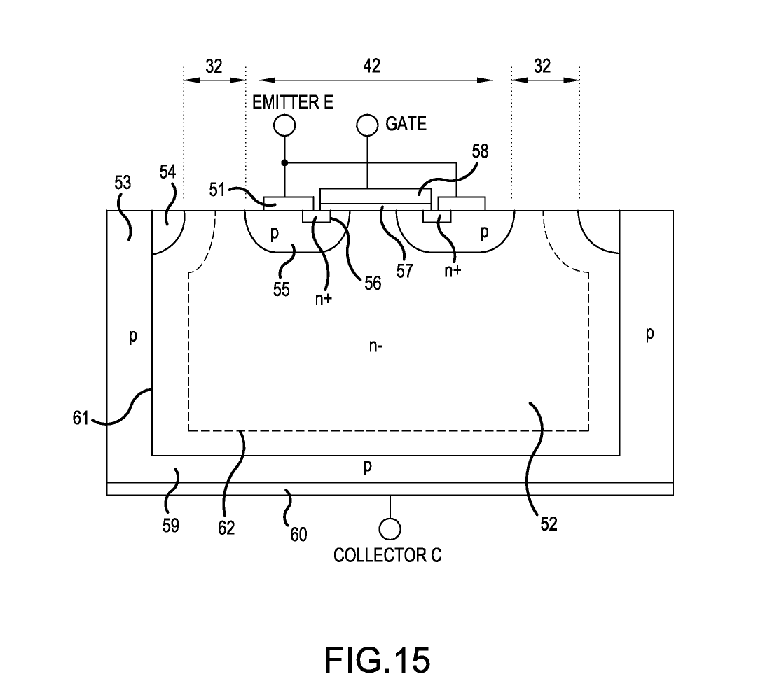

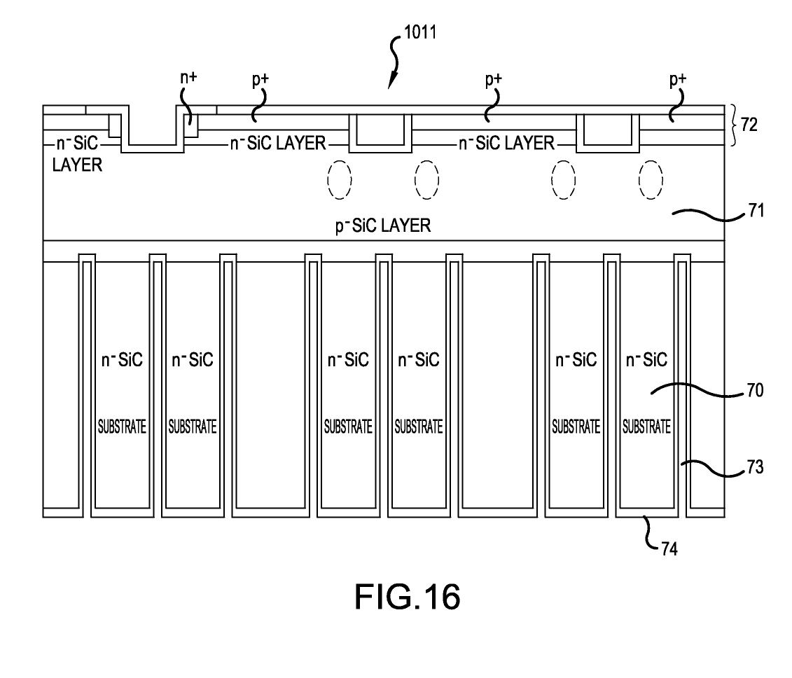

A wide-band-gap reverse blocking MOS semiconductor device according to Embodiment 2 of the invention will be described. FIG. 13 is a cross-sectional view illustrating a main portion of an active region of a SiC reverse blocking MOSFET according to Embodiment 2 of the invention. A SiC reverse blocking MOSFET 1005 according to Embodiment 2 differs from the SiC reverse blocking MOSFET according to Embodiment 1 in that a p-type isolation region 26a is formed along the inner wall of a trench 20 which is provided in the outer circumference of a breakdown voltage structure portion 31. Specifically, the SiC reverse blocking MOSFET 1005 includes the trench 20 that is formed in a peripheral portion of the outer circumference of the breakdown voltage structure portion 31, which is formed so as to surround an active region 41, at a depth that extends from the front surface of a substrate to a p⁺ SiC substrate 100 through a SiC-n J-FET region 4 and a SiC-n⁻ drift layer 1. The p-type isolation region 26a is formed on the inner wall of the trench 20 so as to surround the trench 20.

The p-type isolation region 26a is formed by, for example, the diffusion of impurity ions into the inner wall of the trench 20 by oblique ion implantation and a heat treatment. The trench 20 is filled with an insulating film 21. As such, when the p-type isolation region 26a is formed on the outer circumferential side of the breakdown voltage structure portion 31 so as to surround the active region 41 and the breakdown voltage structure portion 31 and to extend from the surface (the surface opposite to the SiC substrate 100) of the SiC-n⁻ drift layer 1 to the p⁺ SiC substrate 100, a peripheral structure including the trench 20 and the p-type isolation region 26a is not limited to the above-mentioned structure, but may be other structures.

As described above, in the SiC reverse blocking MOSFET according to Embodiment 2, similarly to Embodiment 1, a large amount of current which is sufficient for a power device can flow at a low on-voltage and it is possible to achieve a vertical switching device with high-reliability forward blocking capability and reverse blocking capability.

### Embodiment 3

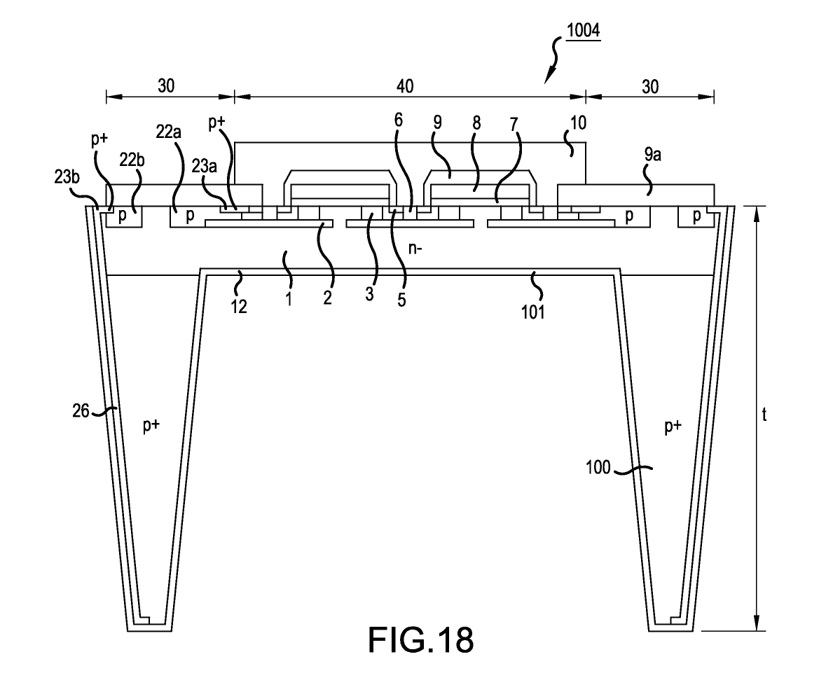

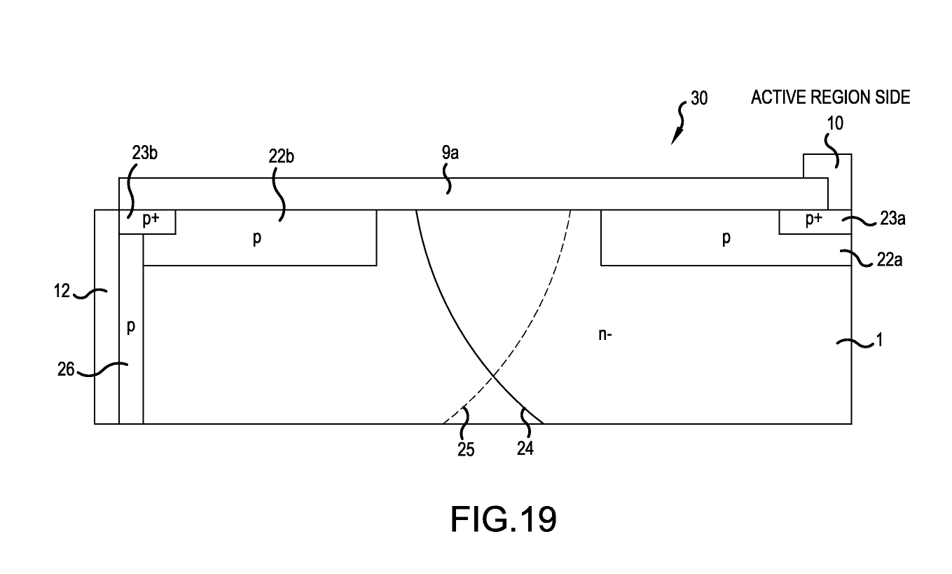

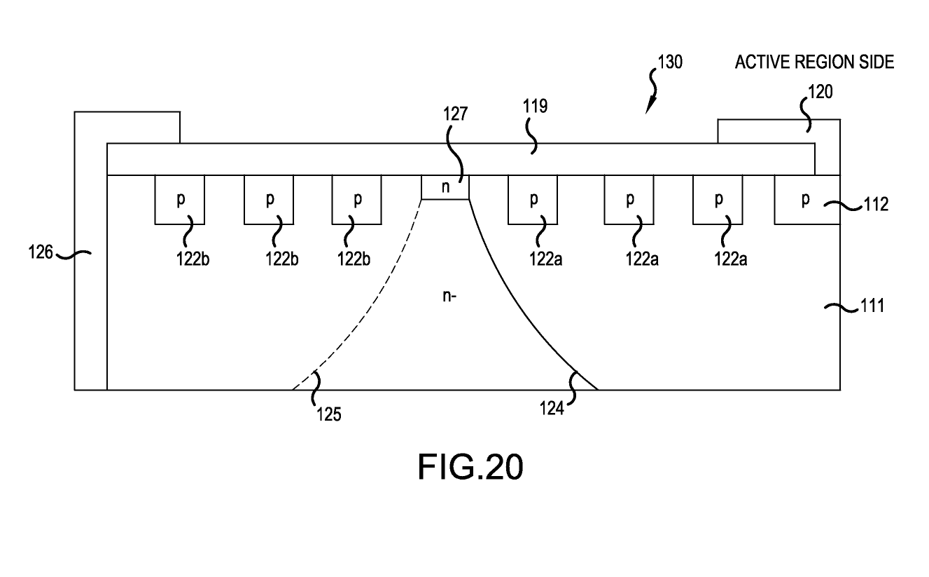

FIG. 18 is a cross-sectional view illustrating the structure of a wide-band-gap reverse blocking MOS semiconductor device according to Embodiment 3 of the invention. FIG. 19 is an enlarged cross-sectional view illustrating a breakdown voltage structure portion illustrated in FIG. 18. In FIG. 19, a p⁺ SiC substrate 100 is not illustrated (which holds for FIGS. 20 to 22 and FIG. 24). The structure of a breakdown voltage structure portion 30 in the SiC reverse blocking MOSFET 1004 according to Embodiment 1 of the invention will be described in detail as Embodiment 3. As illustrated in FIG. 18, the SiC reverse blocking MOSFET 1004 includes a SiC substrate including a p⁺ SiC substrate 100 and a SiC-n⁻ drift layer 1 which is formed on the p⁺ SiC substrate 100. An implantation and epitaxial MOSFET (IE-MOSFET) which is formed by ion implantation and epitaxial growth is provided in an active region 40.

Specifically, in the active region 40, similarly to Embodiment 1, a MOS gate structure including a SiC-p⁺ base region 2, a SiC-p epitaxial region 3, a SiC-n⁺ source region 5, a SiC-p⁺ body region 6, a gate insulating film 7, and a poly-Si gate electrode 8 and a source electrode 10 which is insulated from the poly-Si gate electrode 8 by a BPSG 9 are formed on the front surface (the surface close to the SiC-n⁻ drift layer 1) of the SiC substrate. The SiC-n J-FET region may not be provided. The thickness of the SiC substrate may be equal to or greater than, for example, 50 μm.

Similarly to Embodiment 1, a p-type isolation region 26 is provided on the side surface of the SiC substrate so as to extend from the front surface to the rear surface of the substrate. The side surface of the SiC substrate (an edge portion of a chip) may be inclined at a predetermined angle with respect to the main surface of the substrate. FIG. 18 illustrates a case in which the side surface of the SiC substrate is inclined such that the width of the SiC substrate is gradually reduced from the front surface to the rear surface. Similarly to Embodiment 1, a concave portion 101 is provided in a portion of the rear surface of the SiC substrate, which corresponds to the active region 40, so as to reach the SiC-n⁻ drift layer 1 through the p⁺ SiC substrate 100. In Embodiment 1, the side wall of the concave portion 101 is substantially vertical to the main surface of the substrate. However, as illustrated in FIG. 18, the concave portion 101 may have a side wall with a taper angle. FIG. 18 illustrates a case in which the opening width of the concave portion 101 is gradually reduced from the rear surface to the front surface of the substrate.

Similarly to Embodiment 1, a drain electrode 12 is provided so as to extend from the rear surface (including the inner wall of the concave portion 101) of the SiC substrate to the side surface. The drain electrode 12 forms a Schottky junction with the SiC-n⁻ drift layer 1 on the bottom of the concave portion 101. The drain electrode 12 is connected to the p-type isolation region 26 on the side surface of the substrate. According to this structure, when a reverse voltage is applied, a depletion layer is spread from the pn junction between the SiC-n⁻ drift layer 1 and the p-type isolation region 26 on the side surface of the substrate and it is possible to prevent an increase in a reverse leakage current. In addition, in the structure in which the drain electrode 12 is connected to the p-type isolation region 26 on the side surface of the substrate, when the reverse voltage is applied, a drain potential appears on the front surface of the substrate through the p-type isolation region 26. Therefore, when the reverse voltage is applied or a surge current flows transiently, there is little potential difference between the front surface and the rear surface of the SiC substrate and it is easy to optimize a reverse breakdown voltage structure portion, which will be described below.

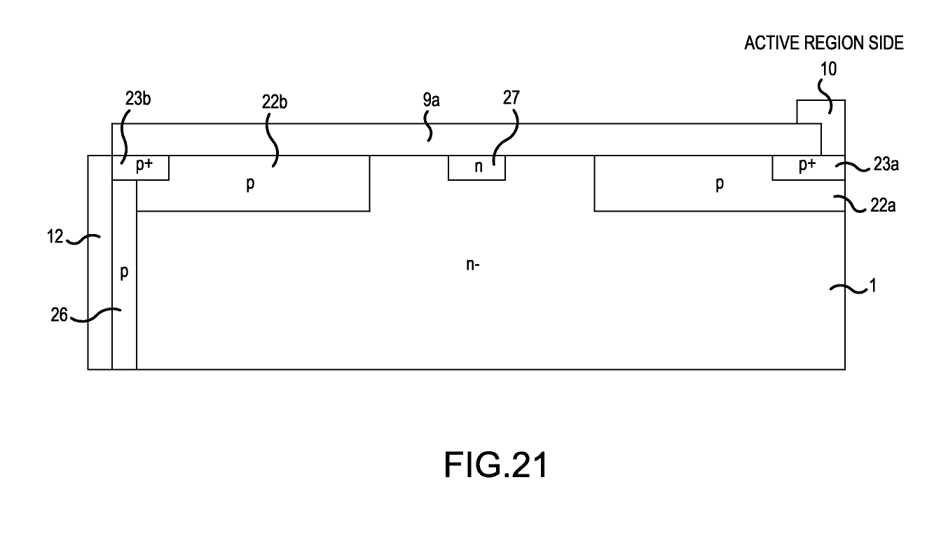

The breakdown voltage structure portion 30 which surrounds the outer circumference of the active region 40 has a JTE structure including SiC-p junction termination extension regions 22a and 22b which are provided on the front surface side of the SiC substrate. The SiC-p junction termination extension region 22a is provided inside the breakdown voltage structure portion 30 and comes into contact with the SiC-p⁺ base region 2 arranged in the outermost circumference. In addition, the SiC-p junction termination extension region 22a is electrically connected to the SiC-n⁺ source region 5 through a p⁺ high-concentration region 23a. In FIG. 19, the SiC-n⁺ source region 5 is not illustrated (which holds for FIGS. 21, 22, and 24). The SiC-p junction termination extension region 22a has a function of ensuring forward blocking capability and forms a forward breakdown voltage structure portion.

The SiC-p junction termination extension region 22b is electrically connected to the p-type isolation region 26 through a p⁺ high-concentration region 23b which is provided outside the breakdown voltage structure portion 30. The SiC-p junction termination extension region 22b has a function of ensuring reverse blocking capability and forms the reverse breakdown voltage structure portion. The front surface of the substrate in the breakdown voltage structure portion 30 is covered with an insulating protective film 9a. As such, the breakdown voltage structure portion 30 includes the forward breakdown voltage structure portion including the SiC-p junction termination extension region 22a, the reverse breakdown voltage structure portion including the SiC-p junction termination extension region 22b, and the insulating protective film 9a.

In a portion of the SiC-n⁻ drift layer 1 which is interposed between the SiC-p junction termination extension region 22a and the SiC-p junction termination extension region 22b, when the forward voltage is applied, a depletion layer 24 is spread from the active region 40 to the p-type isolation region 26. In addition, in the portion of the SiC-n⁻ drift layer 1 which is interposed between the SiC-p junction termination extension region 22a and the SiC-p junction termination extension region 22b, when the reverse voltage is applied, a depletion layer 25 is spread from the p-type isolation region 26 to the active region 40. That is, the portion of the SiC-n⁻ drift layer 1 which is interposed between the SiC-p junction termination extension region 22a and the SiC-p junction termination extension region 22b functions as both the forward breakdown voltage structure portion and the reverse breakdown voltage structure portion.

The length of the portion of the SiC-n⁻ drift layer 1 which is interposed between the SiC-p junction termination extension region 22a and the SiC-p junction termination extension region 22b (the width between the SiC-p junction termination extension region 22a and the SiC-p junction termination extension region 22b) is set such that the depletion layer 24 which is spread from the active region 40 when the forward voltage is applied does not reach the SiC-p junction termination extension region 22b. In addition, the length of the portion of the SiC-n⁻ drift layer 1 which is interposed between the SiC-p junction termination extension region 22a and the SiC-p junction termination extension region 22b is set such that the depletion layer 25 which is spread from the p-type isolation region 26 when the reverse voltage is applied does not reach the SiC-p junction termination extension region 22a.

For comparison, the operation of a wide-band-gap reverse blocking MOS semiconductor device according to the related art which includes a forward breakdown voltage structure portion and a reverse breakdown voltage structure portion, each having an FLR, will be described. FIG. 20 is a cross-sectional view illustrating a breakdown voltage structure portion of the wide-band-gap reverse blocking MOS semiconductor device according to the related art. FIG. 20 corresponds to the breakdown voltage structure portion which is illustrated in, for example, FIG. 1 in Patent Document 7. As illustrated in FIG. 20, in an active region (not illustrated) of the SiC reverse blocking MOSFET according to the related art, a general MOS gate structure is provided on the front surface (the surface close to a SiC-n⁻ drift layer 111) of a semiconductor substrate obtained by forming the SiC-n⁻ drift layer 111 on a p-type Si substrate. Reference numeral 112 is a SiC-p⁺ base region and reference numeral 120 is a source electrode.

A silicon semiconductor region 126 which extends from the front surface of the semiconductor substrate to the p-type Si substrate (not illustrated) through the SiC-n⁻ drift layer 111 is provided on the side surface of the semiconductor substrate. A breakdown voltage structure portion 130 includes a plurality of ring-shaped FLRs 122a and 122b which are provided on the front surface side of the semiconductor substrate and an interlayer insulating film 119 which covers the front surface of the semiconductor substrate. The forward breakdown voltage structure portion is formed by a plurality of FLRs 122a which are provided in the active region. The reverse breakdown voltage structure portion is formed by a plurality of FLRs 122b which are provided in the silicon semiconductor region 126. An n-type stopper region 127 is provided between the FLR 122a provided in the outermost circumference and the FLR 122b provided in the innermost circumference.

In the SiC reverse blocking MOSFET according to the related art, a depletion layer 124 which is spread from the active region to the silicon semiconductor region 126 when the forward voltage is applied is stopped at the end of the n-type stopper region 127 close to the active region. A depletion layer 125 which is spread from the silicon semiconductor region 126 to the active region when the reverse voltage is applied is stopped at the end of the n-type stopper region 127 close to the silicon semiconductor region 126. That is, in the breakdown voltage structure portion 130, the forward breakdown voltage structure portion extends from the end of the n-type stopper region 127, which is close to the active region, to the active region and the reverse breakdown voltage structure portion extends from the end of the n-type stopper region 127, which is close to the silicon semiconductor region 126, to the silicon semiconductor region 126.

As such, in the SiC reverse blocking MOSFET according to the related art, the forward breakdown voltage structure portion and the reverse breakdown voltage structure portion are provided on both sides of the n-type stopper region 127. In contrast, in the SiC reverse blocking MOSFET 1004 according to the invention, the portion of the SiC-n⁻ drift layer 1 which is interposed between the SiC-p junction termination extension region 22a and the SiC-p junction termination extension region 22b can be common to the forward breakdown voltage structure portion and the reverse breakdown voltage structure portion. Therefore, the length of the breakdown voltage structure portion 30 in the SiC reverse blocking MOSFET 1004 according to the invention can be less than that of the breakdown voltage structure portion 130 in the SiC reverse blocking MOSFET according to the related art. In addition, the concentration of the SiC substrate (the impurity concentration of the SiC-n⁻ drift layer 1) is about 100 times more than that of the Si substrate. Therefore, the SiC reverse blocking MOSFET 1004 has a higher charge resistance than the silicon reverse blocking IGBT and it is possible to increase the length of the breakdown voltage structure portion.

A method for manufacturing the SiC reverse blocking MOSFET 1004 illustrated in FIGS. 18 and 19 may form the concave portion 101 and the trench groove 105 for forming the edge portion of the chip using isotropic etching in the method for manufacturing the SiC reverse blocking MOSFET 1004 according to Embodiment 1. The method for manufacturing the SiC reverse blocking MOSFET 1004 illustrated in FIGS. 18 and 19 is the same as the method for manufacturing the SiC reverse blocking MOSFET 1004 according to Embodiment 1 except for the above.

In the method for manufacturing the SiC reverse blocking MOSFET 1004 according to the invention, it is possible to ensure reverse blocking capability, without performing the process of filling the trench with the Si layer to form the silicon semiconductor region 126 in the SiC reverse blocking MOSFET according to the related art. Therefore, the method for manufacturing the SiC reverse blocking MOSFET 1004 according to the invention can also be applied to a case in which a trench with a high aspect ratio is formed in the semiconductor substrate and is suitable for a high-breakdown-voltage reverse blocking device with a thick semiconductor substrate. In addition, since the trench groove 105 which extends from the rear surface to the front surface of the SiC substrate is formed to form the edge portion of the chip, it is not necessary to perform dicing.

As described above, according to Embodiment 3, it is possible to obtain the same effect as that in Embodiments 1 and 2.

### Embodiment 4

FIG. 21 is a cross-sectional view illustrating a breakdown voltage structure portion of a wide-band-gap reverse blocking MOS semiconductor device according to Embodiment 4 of the invention. The SiC reverse blocking MOSFET according to Embodiment 4 differs from the SiC reverse blocking MOSFET according to Embodiment 3 in that an n-type stopper region 27 is provided between a SiC-p junction termination extension region 22a and a SiC-p junction termination extension region 22b. When the n-type stopper region 27 is provided between the SiC-p junction termination extension region 22a and the SiC-p junction termination extension region 22b, it is possible to further suppress the spreading of a depletion layer 24 from an active region 40 to a p-type isolation region 26 and the spreading of a depletion layer 25 from the p-type isolation region 26 to the active region 40.

As described above, according to Embodiment 4, it is possible to obtain the same effect as that in Embodiments 1 to 3.

### Embodiment 5

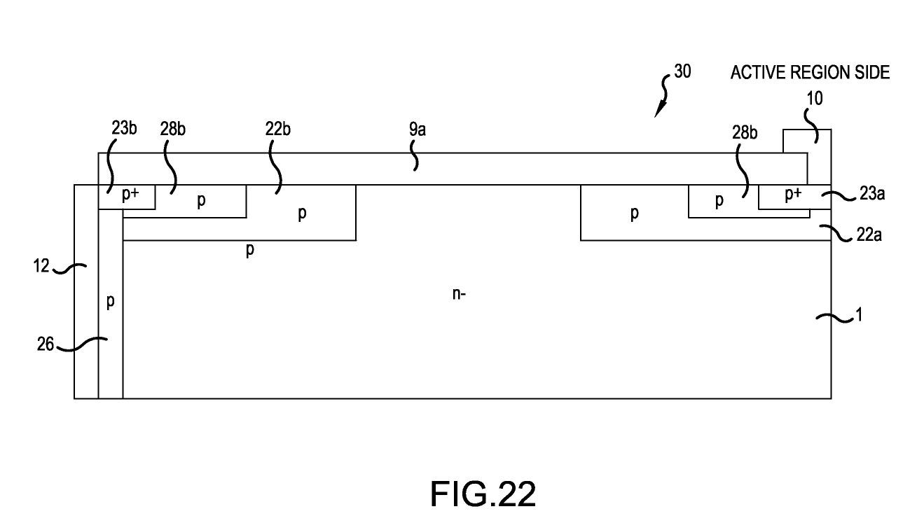

FIG. 22 is a cross-sectional view illustrating a breakdown voltage structure portion of a wide-band-gap reverse blocking MOS semiconductor device according to Embodiment 5 of the invention. The SiC reverse blocking MOSFET according to Embodiment 5 differs from the SiC reverse blocking MOSFET according to Embodiment 3 in that second p-type junction termination extension regions 28a and 28b having a higher impurity concentration than first p-type junction termination extension regions 22a and 22b are provided in SiC-p junction termination extension regions (hereinafter, referred to as first p-type junction termination extension regions) 22a and 22b, respectively.

A forward breakdown voltage structure portion has a two-stage JTE structure including the first p-type junction termination extension region 22a and the second p-type junction termination extension region 28a which is provided in the first p-type junction termination extension region 22a. The second p-type junction termination extension region 28a comes into contact with a p⁺ high-concentration region 23a. A p-type junction termination extension region with impurity concentration that is higher than that of the first p-type junction termination extension region 22a and is lower than that of the second p-type junction termination extension region 28a may be further provided between the first p-type junction termination extension region 22a and the second p-type junction termination extension region 28a to form a forward breakdown voltage structure portion having a JTE structure with three or more stages.

The reverse breakdown voltage structure portion has a two-stage JTE structure including the first p-type junction termination extension region 22b and the second p-type junction termination extension region 28b which is provided in the first p-type junction termination extension region 22b. The second p-type junction termination extension region 28b comes into contact with a p⁺ high-concentration region 23b. A p-type junction termination extension region with impurity concentration that is higher than that of the first p-type junction termination extension region 22b and is lower than that of the second p-type junction termination extension region 28b may be further provided between the first p-type junction termination extension region 22b and the second p-type junction termination extension region 28b to form a reverse breakdown voltage structure portion having a JTE structure with three or more stages.

As described above, according to Embodiment 5, it is possible to obtain the same effect as that in Embodiments 1 to 4.

### Embodiment 6

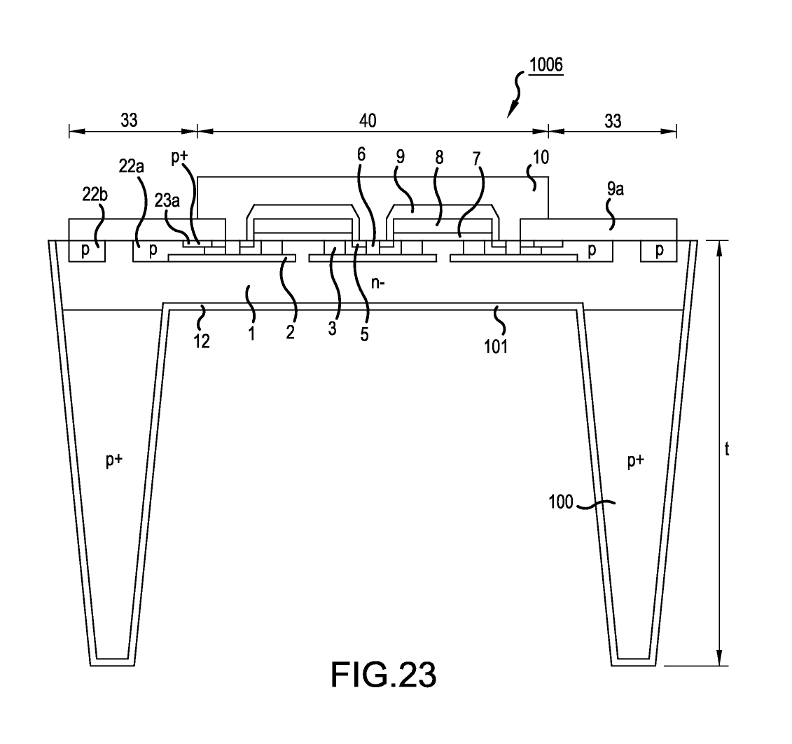

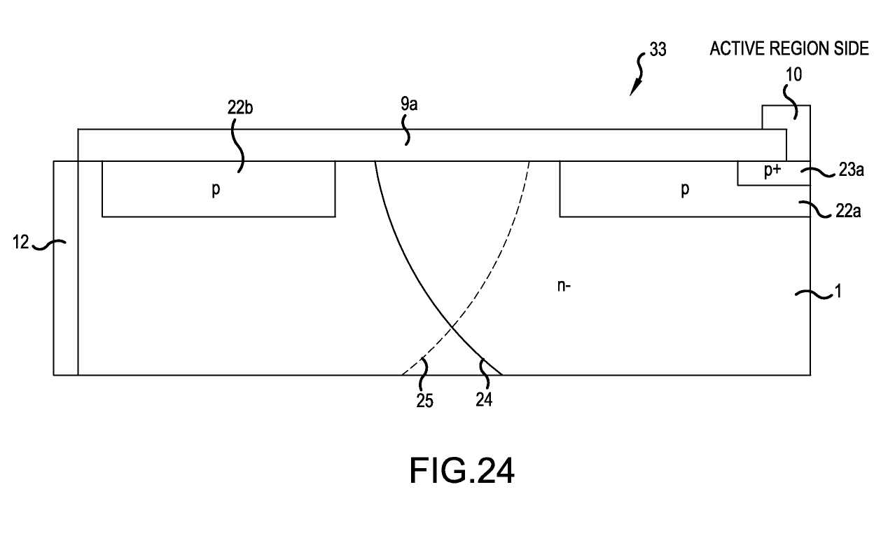

FIG. 23 is a cross-sectional view illustrating the structure of a wide-band-gap reverse blocking MOS semiconductor device according to Embodiment 6 of the invention. FIG. 24 is an enlarged cross-sectional view illustrating a breakdown voltage structure portion illustrated in FIG. 23. A SiC reverse blocking MOSFET 1006 according to Embodiment 6 differs from the SiC reverse blocking MOSFET according to Embodiment 3 in that the p-type isolation region is not provided on the side surface of the substrate and a Schottky junction between a drain electrode 12 and a SiC-n⁻ drift layer 1 is formed on the side surface of substrate side.

In the SiC reverse blocking MOSFET 1006 according to Embodiment 6, reverse blocking capability is ensured by the Schottky junction formed on the side surface of the substrate. Therefore, similarly to Embodiment 1, in a breakdown voltage structure portion 33, a portion of a SiC-n⁻ drift layer 1 which is interposed between a SiC-p junction termination extension region 22a and a SiC-p junction termination extension region 22b functions as both a forward breakdown voltage structure portion and a reverse breakdown voltage structure portion.

As described above, according to Embodiment 6, it is possible to obtain the same effect as that in Embodiments 1 to 5. In addition, according to Embodiment 6, when a reverse voltage is applied, a depletion layer is spread from the Schottky junction formed on the side surface of the substrate. Therefore, it is possible to prevent an increase in a reverse leakage current, similarly to the case in which the pn junction between the p-type isolation region and the SiC-n⁻ drift layer is formed on the side surface of the substrate.

The invention is not limited to the above-described embodiments, but various modifications and changes of the invention can be made without departing from the scope and spirit of the invention. In each of the above-described embodiments, for example, the dimensions or surface concentration of each component varies depending on the required specifications. In each of the above-described embodiments, the semiconductor device having the MOS gate structure is given as an example. However, the semiconductor device may have a metal-insulator-semiconductor insulated gate (MIS gate) structure.

As described above, the semiconductor device according to the invention is useful for a power semiconductor device that is used in a power conversion device, such as an inverter or a converter requiring high reliability for the application of a reverse voltage between a drain and a source.

What is claimed is:

1. A semiconductor device comprising:
a first-conductivity-type semiconductor layer that is made of a semiconductor material with a wider band gap than silicon and is grown on one main surface of a semiconductor substrate of a second conductivity type;
an active region that is formed on a surface of the first-conductivity-type semiconductor layer opposite to the semiconductor substrate and includes an insulated gate structure;
a breakdown voltage structure portion that surrounds the outer circumference of the active region;
a concave portion that is provided in a region of the other main surface of the semiconductor substrate, which is opposite to the active region, at a depth that reaches the first-conductivity-type semiconductor layer through the semiconductor substrate and has an area corresponding to the area of the active region; and
a metal film that is provided along an inner wall of the concave portion and comes into contact with the first-conductivity-type semiconductor layer on the bottom of the concave portion to form a Schottky junction.

2. The semiconductor device according to claim 1,
wherein an angle that is formed between the surface of the first-conductivity-type semiconductor layer opposite to the semiconductor substrate and an outermost circumferential current path of a main current which flows through the first-conductivity-type semiconductor layer between the active region and the concave portion is equal to or greater than 45 degrees.

3. The semiconductor device according to claim 1, further comprising:
a second-conductivity-type isolation layer that is provided in a portion of the first-conductivity-type semiconductor layer, which surrounds the outer circumference of the breakdown voltage structure portion, so as to pass through the first-conductivity-type semiconductor layer in a depth direction and to reach the semiconductor substrate.

4. The semiconductor device according to claim 3,
wherein the second-conductivity-type isolation layer is arranged along a side wall of a trench which is formed at a depth that extends from the other main surface of the semiconductor substrate to the surface of the first-conductivity-type semiconductor layer opposite to the semiconductor substrate.

5. The semiconductor device according to claim 4,
wherein the metal film is provided on the other main surface of the semiconductor substrate and the inner wall of the trench and is connected to the second-conductivity-type isolation layer on the side wall of the trench.

6. The semiconductor device according to claim 1,
wherein the metal film is arranged along a side wall of a trench which is formed at a depth that extends from the other main surface of the semiconductor substrate to the surface of the first-conductivity-type semiconductor layer opposite to the semiconductor substrate.

7. The semiconductor device according to claim 6,
wherein the metal film comes into contact with the first-conductivity-type semiconductor layer on the side wall of the trench to form a Schottky junction.

8. The semiconductor device according to claim 1,
wherein the breakdown voltage structure portion includes:
a forward breakdown voltage structure portion including a first junction termination region of the second conductivity type which is provided in a surface layer of the surface of the first-conductivity-type semiconductor layer opposite to the semiconductor substrate and in which a depletion layer is spread from the active region to outer circumference when a forward voltage is applied; and
a reverse breakdown voltage structure portion including a second junction termination region of the second conductivity type which is provided in the surface layer of the surface of the first-conductivity-type semiconductor layer opposite to the semiconductor substrate so as to be closer to the outer circumference than the first junction termination region and in which the depletion layer is spread from the outer circumference to the active region when a reverse voltage is applied.

9. The semiconductor device according to claim 8, further comprising:
a third junction termination region of the second conductivity type that is provided in the first junction termination region and has a higher impurity concentration than the first junction termination region; and
a fourth junction termination region of the second conductivity type that is provided in the second junction termination region and has a higher impurity concentration than the second junction termination region.

10. The semiconductor device according to claim 8,
wherein a portion of the first-conductivity-type semiconductor layer which is interposed between the first junction termination region and the second junction termination region functions as both the forward breakdown voltage structure portion and the reverse breakdown voltage structure portion.

11. The semiconductor device according to claim 1,
wherein the first-conductivity-type semiconductor layer is a gallium nitride semiconductor layer.

12. The semiconductor device according to claim 1,
wherein the semiconductor device is an insulated gate field effect transistor having the insulated gate structure including a metal film, an oxide film, and a semiconductor film or the insulated gate structure including a metal film, an insulating film, and a semiconductor film.
